(19) United States
(12) Patent Application Publication
(10) Pub. No.: US 2014/0138850 A1
(43) Pub. Date: May 22, 2014

(54) SEMICONDUCTOR POWER MODULE, PRODUCTION METHOD OF SEMICONDUCTOR POWER MODULE AND CIRCUIT BOARD

(71) Applicant: Yasushi Takayama, Aichi-ken (JP)

(72) Inventor: Yasushi Takayama, Aichi-ken (JP)

(73) Assignee: NGK SPARK PLUG CO., LTD., Nagoya-shi, Aichi (JP)

(21) Appl. No.: 14/234,323

(22) PCT Filed: Jul. 31, 2012
(86) PCT No.: PCT/JP2012/004865

§ 371 Date: Jan. 22, 2014

(30) Foreign Application Priority Data
Aug. 1, 2011 (JP) 2011-168295
Aug. 1, 2011 (JP) 2011-168296
Mar. 19, 2012 (JP) 2012-061859

(51) Int. Cl. H01L 23/36; H01L 23/48; H01L 21/50; H05K 7/20

(52) U.S. Cl. CPC H01L 23/36; H05K 7/205; H01L 23/481; H01L 21/50
USPC 257/774; 361/736; 438/455

(57) ABSTRACT

A semiconductor power module (10) includes a ceramic multilayer substrate (100), a bonding layer (110), a diffusion layer (120) and a semiconductor device (130). The bonding layer is placed on a first surface (105) of the ceramic multilayer substrate and is provided as a planar thin film layer including conductive bonding parts (111) configured to electrically connect the semiconductor device with the ceramic multilayer substrate and insulating bonding parts (112) configured to isolate the semiconductor device from the ceramic multilayer substrate. Also disclosed is a production method of the semiconductor power module.

### TECHNICAL FIELD

The present invention relates to a semiconductor power module having a semiconductor device mounted on a circuit board, a production method of a semiconductor power module and a circuit board.

### BACKGROUND ART

With recent advances of small-size, low-profile and high-density mounting for power module packaging, as the alternative of the conventional mounting scheme using wire bonding, a mounting scheme that uses a ceramic multilayer substrate and makes flip chip connection of a semiconductor device has been proposed for production of semiconductor modules. The flip chip connection is a bonding method that arranges conductive projections called bumps on a semiconductor device, adjusts the bumps to the location where the semiconductor device is to be mounted on the ceramic multilayer substrate and directly bonds the semiconductor device to the ceramic multilayer substrate. This mounting scheme reduces the area required for mounting the semiconductor device by about 20 to 30% and has contribution to the high-density mounting.

In some proposed semiconductor modules by such flip chip mounting scheme, as the alternative of an organic material conventionally used as the sealing material, an inorganic material is filled in the gaps of the bumps between the ceramic multilayer substrate and the semiconductor device (for example, Patent Literature 1).

### CITATION LIST

### Patent Literature

PTL 1: JP 2004-253579A
PTL 2: JP 2006-066582A
PTL 3: JP 2010-287869A
PTL 4: JP 2009-170930A

### SUMMARY OF INVENTION

### Technical Problem

In the semiconductor power modules with the advancement of the higher-density mounting by the flip chip mounting scheme, reduction of the heat radiation area results in deteriorating the heat radiation performance by the size effect. It is accordingly required to further improve the heat diffusion performance from the semiconductor device to the ceramic multilayer substrate. In the conventional semiconductor power modules, however, there are problems that voids are produced between the ceramic multilayer substrate and the semiconductor device due to the occurrence of gas bubbles in the process of filling the sealing material or the occurrence of cracks at the junction caused by a thermal stress during use and that the air enters such voids. Accordingly, the conventional semiconductor power modules have problems, such as degradation of the heat radiation performance of the semiconductor device due to reduction of the heat diffusion performance from the semiconductor device to the ceramic multilayer substrate, reduction of the bond strength between the ceramic multilayer substrate and the semiconductor device and deterioration of the reliability. The conventional semiconductor power modules also have problems, such as poor electrical connection caused by manufacturing variation among the structural components, which may be attributed to little warpage of the ceramic multilayer substrate. It is accordingly desired to provide a module configuration and a production process that are unlikely to cause deterioration of the reliability.

### Solution to Problem

In order to solve at least part of the problems described above, the invention provides aspects and embodiments described below.

(1) In one aspect of the present invention, there is provided a semiconductor power module. The semiconductor power module comprises: a multilayer substrate having a via and an interconnecting pattern formed thereon; a semiconductor device placed on a first surface side of the multilayer substrate; and a bonding layer formed on the first surface of the multilayer substrate for bonding the multilayer substrate to the semiconductor device, and wherein the bonding layer includes: a planar conductive bonding part arranged at a first region corresponding to the via and configured to have a conductive projection formed on the semiconductor device and a conductive connector arranged to provide electrical continuity between the projection and the multilayer substrate; and a planar insulating bonding part arranged at a second region different from the first region and made of an inorganic material as a main constituent. In the semiconductor power module according to this aspect, the bonding layer is made planar. This configuration suppresses the occurrence of voids between the multilayer substrate and the semiconductor device when the multilayer substrate is bonded to the semiconductor device. This accordingly improves the heat diffusion performance from the semiconductor devices to the multilayer substrate and the bond strength between the multilayer substrate and the semiconductor device.

(2) In the semiconductor power module according to above described aspect, the multilayer substrate and the bonding layer may be bonded by diffusion bonding, and the semiconductor device and the bonding layer may be bonded by diffusion bonding, and the semiconductor power module may further comprise: a diffusion layer formed between the multilayer substrate and the bonding layer and between the semiconductor device and the bonding layer during the diffusion bonding. In the semiconductor power module according to this aspect, the diffusion layer is formed by diffusion of atoms occurring at the interface between the multilayer substrate and the bonding layer and at the interface between the bonding layer and the semiconductor device during diffusion bonding between the multilayer substrate and the bonding layer and between the bonding layer and the semiconductor device. This improves the bond strength between the multilayer substrate and the bonding layer and the bond strength between the bonding layer and the semiconductor device.

(3) In the semiconductor power module according to above described aspect, a first bonding start temperature which is a bonding start temperature of a material constituting the conductive bonding part may be lower than a second bonding start temperature which is a bonding start temperature of a material constituting the insulating bonding part. In the semiconductor power module according to this aspect, the conductive bonding part is bonded, prior to the insulating bonding part. Accordingly, in the state that the conductive connector is bonded to the projection of the semiconductor device and that the conductive bonding part is bonded to the interconnecting substrate, i.e., in the state that there is no void between the conductive connector and the projection of the semiconductor device and between the conductive bonding part and the interconnecting substrate, the insulating bonding part starts softening and deforming, so as to be bonded to the semiconductor device and to the interconnecting substrate. This configuration suppresses deterioration of the conductive performance of the conductive bonding part due to invasion of the material constituting the insulating bonding part between the conductive connector and an electrode pad, i.e., mixing of the material into the conductive bonding part.

(4) In the semiconductor power module according to above described aspect, the first bonding start temperature may be equal to or higher than a sintering start temperature at which at least part of the material constituting the conductive bonding part starts a sintering reaction, and the second bonding start temperature may be equal to or higher than a sintering start temperature at which at least part of the material constituting the insulating bonding part starts a sintering reaction. In the semiconductor power module according to this aspect, the first bonding start temperature is equal to or higher than the temperature at which at least part of the material constituting the conductive bonding part starts the sintering reaction. The second bonding start temperature is equal to or higher than the temperature at which at least part of the material constituting the insulating bonding part starts the sintering reaction. Accordingly this enables each of the conductive bonding part and the insulating bonding part to be bonded to another member without being heating to the melting point. In another example, the first bonding start temperature may be a melting start temperature of the material constituting the conductive bonding part, and the second bonding start temperature may be a melting start temperature of the material constituting the insulating bonding part. This ensures the conductive bonding part and the insulating bonding part to be effectively melted, thus improving the bond strength between each of the conductive bonding part and the insulating bonding part with another member.

(5) In one aspect of the present invention, there is provided a production method of a semiconductor power module. The production method of a semiconductor power module comprises: a substrate manufacturing step that manufactures a multilayer substrate having a via and an interconnecting pattern; a first placement step that places a bonding part on a first surface of the multilayer substrate, wherein the bonding part has a planar conductive connector for providing electrical continuity between the interconnecting pattern and a semiconductor device at a first region corresponding to the via and a planar insulating bonding part at a second region different from the first region; a second placement step that places the semiconductor device on the bonding part such as to provide electrical continuity between a conductive projection formed on the semiconductor device and the conductive connector; and a bonding step that bonds the multilayer substrate, the bonding part and the semiconductor device by application of heat and pressure, so as to make diffusion bonding between the multilayer substrate and the bonding part and between the bonding part and the semiconductor device. In the production method of the semiconductor power module according to this aspect, the planar bonding layer for bonding the multilayer substrate to the semiconductor device is formed by the bonding part and the projection between the multilayer substrate and the semiconductor device. This configuration suppresses the occurrence of voids between the multilayer substrate and the semiconductor device. Accordingly this improves the heat diffusion performance from the semiconductor device to the multilayer substrate and the bond strength between the multilayer substrate and the semiconductor device.

(6) In the production method of a semiconductor power module according to above described aspect, a first bonding start temperature may be a temperature at which a material constituting the conductive connector starts bonding to the semiconductor device, and a second bonding start temperature may be a temperature at which a material constituting the insulating bonding part starts bonding to the multilayer substrate and to the semiconductor device and which is higher than the first bonding start temperature, wherein the bonding step may include: a step of bonding the multilayer substrate, the bonding part and the semiconductor device by application of pressure and heat at the first bonding start temperature, so as to bond the conductive connector to the projection of the semiconductor device; and a step of bonding the multilayer substrate, the bonding part and the semiconductor device by application of pressure and heat at the second bonding start temperature, so as to bond the multilayer substrate to the bonding part and bond the bonding part to the semiconductor device, after the conductive connector is bonded to the projection of the semiconductor device. In the production method of the semiconductor power module according to this aspect, the conductive bonding part is bonded, prior to the insulating bonding part. Accordingly, in the state that the conductive connector is bonded to the projection of the semiconductor device and that the conductive connector is bonded to the interconnecting substrate, i.e., in the state that there is no void between the conductive connector and the projection of the semiconductor device and between the conductive connector and the interconnecting substrate, the insulating bonding part starts softening and deforming, so as to be bonded to the semiconductor device and to the interconnecting substrate. This configuration suppresses deterioration of the conductive performance of the conductive connector due to invasion of the material constituting the insulating bonding part between the conductive connector and the projection, i.e., mixing of the material into the conductive connector.

(7) In the production method of a semiconductor power module according to above described aspect, the first bonding start temperature may be equal to or higher than a sintering start temperature at which at least part of the material constituting the conductive connector starts a sintering reaction, and the second bonding start temperature may be equal to or higher than a sintering start temperature at which at least part of the material constituting the insulating bonding part starts a sintering reaction. In the production method of the semiconductor power module according to this aspect, the first bonding start temperature is equal to or higher than the temperature at which at least part of the material constituting the conductive connector starts the sintering reaction. The second bonding start temperature is equal to or higher than the temperature at which at least part of the material constituting the insulating bonding part starts the sintering reaction. Accordingly this enables each of the conductive connector and the insulating bonding part to be bonded to another member without being heating to the melting point. In another example, the first bonding start temperature may be a melting start temperature of the material constituting the conductive connector, and the second bonding start temperature may be a melting start temperature of the material constituting the insulating bonding part. This ensures the conductive connector and the insulating bonding part to be effectively melted, thus improving the bond strength between each of the conductive connector and the insulating bonding part with another member.

(8) In the production method of a semiconductor power module according to above described aspect, a first bonding start temperature may be a temperature at which a material constituting the conductive connector starts bonding to the semiconductor device, and a second bonding start temperature may be a temperature at which a material constituting the insulating bonding part starts bonding to the multilayer substrate and to the semiconductor device and which is higher than the first bonding start temperature, wherein the bonding step may perform the application of heat, based on a temperature profile which is set to maintain the first bonding start temperature for a predetermined time and subsequently maintain the second bonding start temperature for a predetermined time. In the production method of the semiconductor power module according to this aspect, the bonding part, the interconnecting substrate and the semiconductor device are bonded, based on the temperature profile having a stepwise temperature change. Accordingly, this enables diffusion bonding to be made with a stepwise temperature change by the simple configuration, thus improving the production efficiency.

(9) In the production method of a semiconductor power module according to above described aspect, the first placement step may include: a step of placing the insulating bonding part having an opening portion at the first region on the first surface; and a step of placing the conductive connector made thinner than the insulating bonding part in the opening portion, and the second placement step may include: a step of placing the semiconductor device on the bonding part such that the projection is fit in the opening portion, so as to provide electrical continuity between the projection of the semiconductor device and the conductive connector, and wherein d3>d2−d1 may be satisfied where d1 represents a thickness of the conductive connector, d2 represents a thickness of the insulating bonding part and d3 represents a height of the projection. In the production method of the semiconductor power module according to this aspect, the conductive connector and the insulating bonding part are formed to satisfy d3>d2−d1 where d1 represents the thickness of the conductive connector, d2 represents the thickness of the insulating bonding part and d3 represents the thickness of the projection. This accordingly enables the semiconductor device to be placed in the recess in the state that good electrical connection is ensured between the projection and the conductive connector. In this state, the semiconductor device is off the surface of the bonding layer when the semiconductor device is placed on the bonding layer. The bonding process, however, applies heat to melt the projection and applies pressure in this molten state, so that the semiconductor device is bonded to the bonding layer via a void-free plane.

(10) In the production method of a semiconductor power module according to above described aspect, the step of placing the insulating bonding part may arrange the insulating bonding part to be in such a shape that narrows from an end bonded to the semiconductor device toward an end bonded to the multilayer substrate. In the production method of the semiconductor power module according to this aspect, the insulating bonding part is formed in such a shape that narrows from the semiconductor device side toward the multilayer substrate side. This configuration provides the wider contact area between the semiconductor device and the insulating bonding part, compared with the contact area between the semiconductor device and the insulating bonding part that is formed in an approximately columnar shape. This accordingly improves the heat diffusion performance from the semiconductor device to the multilayer substrate, while ensuring the bond strength and the insulation performance between the multilayer substrate and the semiconductor device.

(11) In the production method of a semiconductor power module according to above described aspect, the step of placing the insulating bonding part may arrange the insulating bonding part to be in a tapered shape. In the production method of the semiconductor power module according to this aspect, the insulating bonding part is formed in a tapered shape. This configuration enables the insulating bonding part to be readily formed in such a shape that narrows from the semiconductor device side toward the multilayer substrate side.

(12) In one aspect of the present invention, there is provided a circuit board. The circuit board comprises: a multilayer substrate having a via and an interconnecting pattern formed thereon; and a bonding layer formed on a first surface of the multilayer substrate for bonding the multilayer substrate to a semiconductor device, wherein the bonding layer includes: a conductive connector arranged at a first region corresponding to the via and configured to provide electrical continuity with the interconnecting pattern and with the semiconductor device, wherein at least a first surface-side surface of the conductive connector is made planar; and an insulating bonding part arranged at a second region different from the first region and made of an inorganic material as a main constituent, wherein at least a first surface-side surface of the insulating bonding part is made planar. In the circuit board according to this aspect, the semiconductor device and the multilayer substrate are bonded via a plane. This suppresses the occurrence of voids between the multilayer substrate and the semiconductor device. Accordingly this improves the heat diffusion performance from the semiconductor device to the multilayer substrate and the bond strength between the multilayer substrate and the semiconductor device.

(13) In the circuit board according to above described aspect, the conductive connector may be made thinner than the insulating bonding part, and the bonding layer may have a recess formed by the insulating bonding part and the conductive connector, and wherein before a conductive projection formed on the semiconductor device is fit in the recess, d3>d2−d1 may be satisfied where d1 represents a thickness of the conductive connector, d2 represents a thickness of the insulating bonding part and d3 represents a height of the projection. In the circuit board according to this aspect, with respect to fitting of the projection into the recess, the conductive connector and the insulating bonding part are formed to satisfy d3>d2−d1 where d1 represents the thickness of the conductive connector, d2 represents the thickness of the insulating bonding part and d3 represents the thickness of the projection. This configuration ensures the good electrical connection between the projection and the conductive connector when the semiconductor device is set in the recesses.

(14) In the circuit board according to above described aspect, the insulating bonding part may be formed in such a shape that narrows from an end bonded to the semiconductor device toward an end bonded to the multilayer substrate. In the circuit board according to this aspect, the insulating bonding part is formed in such a shape that narrows from the semiconductor device side toward the multilayer substrate side. This configuration provides the wider contact area between the semiconductor device and the insulating bonding part, compared with the contact area between the semiconductor device and the insulating bonding part that is formed in an approximately columnar shape. This accordingly improves the heat diffusion performance from the semiconductor device to the multilayer substrate, while ensuring the bond strength and the insulation performance between the multilayer substrate and the semiconductor device.

(15) In the circuit board according to above described aspect, the insulating bonding part may be formed in a tapered shape. In the circuit board according to this aspect, the insulating bonding part is formed in a tapered shape. This configuration enables the insulating bonding part to be readily formed in such a shape that narrows from the semiconductor device side toward the multilayer substrate side.

The plurality of structural components included in each aspect of the invention described above are not all essential, but some structural components among the plurality of structural components may be appropriately changed, omitted or replaced with other structural components or part of the limitations may be deleted, in order to solve part or all of the problems described above or in order to achieve part or all of the advantageous effects described herein. In order to solve part or all of the problems described above or in order to achieve part or all of the advantageous effects described herein, part or all of the technical features included in one aspect of the invention described above may be combined with part or all of the technical features included in another aspect of the invention described above to provide still another independent aspect of the invention.

### BRIEF DESCRIPTION OF THE DRAWINGS

FIG. 1 is a cross sectional diagram illustrating the schematic configuration of a semiconductor power module 10 according to a first embodiment;

FIG. 2 is a diagram illustrating a circuit board 20 according to the first embodiment;

FIG. 3 is a flowchart showing a production method of the semiconductor power module 10 according to the first embodiment;

FIG. 4 is a diagram illustrating the process of arranging the conductive connectors 111a at step S12;

FIG. 5 is a diagram illustrating screen printing of the insulating bonding parts 112 at step S14;

FIG. 6 is a diagram illustrating the bonding process of the semiconductor power module 10 according to the first embodiment;

FIG. 7 is a plan view illustrating a semiconductor power module 30 according to the second embodiment;

FIG. 8 is a cross sectional view illustrating the semiconductor power module 30 of the second embodiment;

FIG. 9 is a cross sectional view illustrating a semiconductor power module 40 according to a fourth embodiment;

FIG. 10 is a cross sectional view illustrating the schematic configuration of a semiconductor power module 1010 according to a fifth embodiment;

FIG. 11 is a diagram illustrating the semiconductor power module 1010 of the fifth embodiment;

FIG. 12 is a flowchart showing a production method of the semiconductor power module 1010 according to the fifth embodiment;

FIG. 13 is a diagram illustrating the process of arranging the insulating bonding part 512 at step S102;

FIG. 14 is a diagram illustrating the process of creating the opening portions 515 at step S104;

FIG. 15 is a diagram illustrating the process of arranging the conductive connectors 511 at step S106;

FIG. 16 is a diagram illustrating the bonding process of the semiconductor power module 1010 according to the fifth embodiment;

FIG. 17 is a sectional view illustrating the configuration of a semiconductor power module 1030 according to a sixth embodiment;

FIG. 18 is a sectional view illustrating the configuration of a semiconductor power module 1030 according to a sixth embodiment;

FIG. 19 is a diagram illustrating the schematic configuration of a semiconductor power 1040 according to Modification 5;

FIG. 20 is a diagram illustrating the process of arranging the bonding layer 810 in Modification 5;

FIG. 21 is a plan view illustrating a semiconductor power module 1050 according to Modification 6; and

FIG. 22 is a cross sectional view illustrating the semiconductor power module 1050 of Modification 6.

### DESCRIPTION OF EMBODIMENTS

### A. First Embodiment

### A1. Schematic Configuration of Semiconductor Power Module

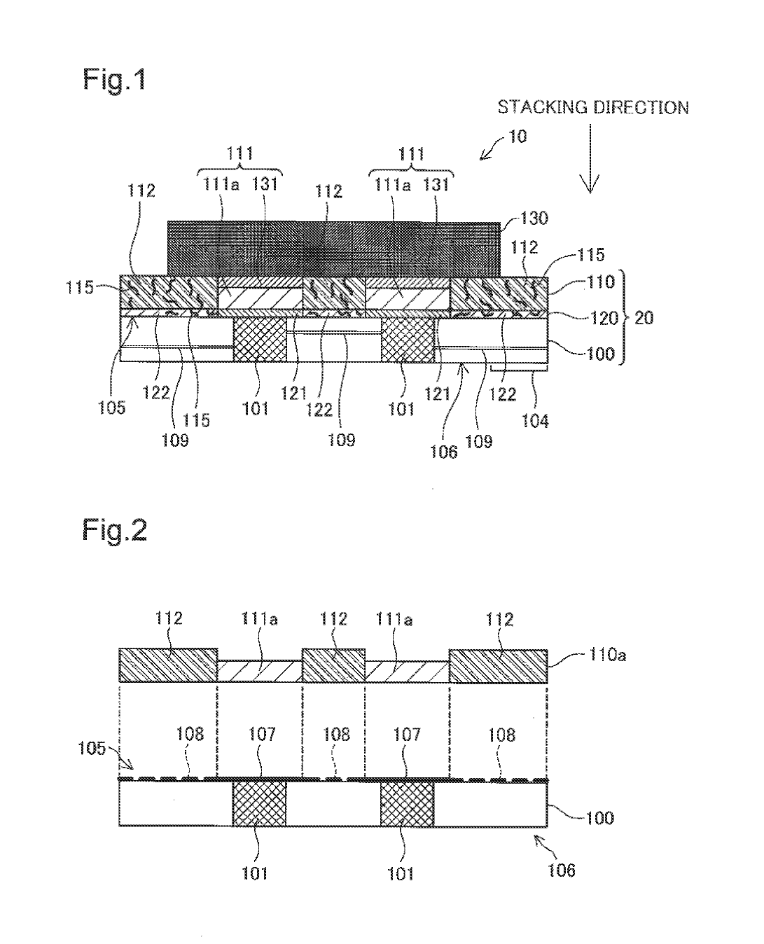

FIG. 1 is a cross sectional diagram illustrating the schematic configuration of a semiconductor power module 10 according to a first embodiment. FIG. 2 is a diagram illustrating a circuit board 20 according to the first embodiment. The semiconductor power module 10 includes a circuit board 20 and a semiconductor device 130. The circuit board 20 includes a ceramic multilayer substrate 100, a bonding layer 110 and a diffusion layer 120.

The ceramic multilayer substrate 100 is made of a ceramic material. As the ceramic material used may be, for example, aluminum oxide (Al₂O₃), aluminum nitride (AlN) or silicon nitride (Si₃N₄). The ceramic multilayer substrate 100 includes a first surface 105 with the semiconductor device mounted thereon, inner layer via holes 101 each arranged to electrically connect the first surface 105 with the other surface or a second surface 106 opposed to the first surface 105 and configured to mount other electronic components such as a control circuit and a capacitor, interconnecting patterns 109 and an electrode terminal 104 for external connection placed on the second surface 106. The interconnecting patterns 109 are formed on the surfaces of the ceramic multilayer substrate 100 and the surfaces of inner layers. The interconnecting patterns formed on the surfaces of the ceramic multilayer substrate 100 are omitted from illustration of FIG. 1. Electrode lands (not shown) for mounting the semiconductor device 130 and other electronic components are formed on the first surface 105 and the second surface 106 of the ceramic multilayer substrate 100. The semiconductor device 130 is electrically connected with the electrode terminal 104 placed on the second surface 106 via the inner layer via holes 101 and the interconnecting patterns 109.

The bonding layer 110 is placed on the first surface 105 of the ceramic multilayer substrate 100 and is provided as a planar thin film layer including conductive bonding parts 111 and insulating bonding parts 112.

The conductive bonding parts 111 include conductive connectors 111a and electrode pads 131 of the semiconductor device 130 and are arranged to electrically connect the semiconductor device 130 with the ceramic multilayer substrate 100. The conductive connectors 111a are made of a conductive metal as the main constituent and are arranged on the first surface 105 of the ceramic multilayer substrate 100 or specifically at first regions 107 (shown by the thick solid line) corresponding to the inner layer via holes 101 as shown in FIG. 2. For example, copper, silver or metal aluminum may be used as the conductive metal. The conductive connectors 111a are made thinner than the insulating bonding parts 112 as described below, so that recesses are formed by the insulating bonding parts 112 and the conductive connectors 111a. The electrode pads 131 are arranged to be fit in the recesses, so as to form the conductive bonding parts 111. The electrode pads 131 of the first embodiment correspond to the “protruded part” of the claims. The same applies to second to fourth embodiments described later.

The insulating bonding parts 112 isolate the semiconductor device 130 from the ceramic multilayer substrate 100. As shown in FIG. 2, the insulating bonding parts 112 are arranged on the first surface 105 of the ceramic multilayer substrate 100 or specifically at second regions 108 (shown by the thick broken line) different from the first regions 107. The insulating bonding parts 112 are made of powder glass, which is made of an insulating inorganic material as the main constituent and is softened in a heating process in the course of mounting the semiconductor device. The powder glass may be formed to have a multiphase of, for example, silicon oxide, zinc oxide, boron oxide and bismuth oxide, such as ZnO—B₂O₃—SiO₂.

According to the first embodiment, the second regions 108 cover the residual area other than the first regions 107 or the regions where the conductive bonding parts 111 are placed. The conductive bonding parts 111 and the insulating bonding parts 112 have substantially the same thicknesses to enable the bonding layer 110 to form a uniform plane. A surface of the bonding layer 110 opposed to the semiconductor device 130 also forms a uniform plane.

In this embodiment, the uniform plane may include minute curvatures and irregularities. The bonding layer 110 forming the uniform plane includes that the surface of the bonding layer 110 opposed to the first surface 105 of the ceramic multilayer substrate is formed along the shape of the first surface 105 and the conductive bonding parts 111 and the insulating bonding parts 112 are continuously made flat, and that the surface of the bonding layer 110 opposed to the semiconductor device 130 is formed along the shape of an opposing surface of the semiconductor device 130 opposed to the bonding layer 110.

It is preferable that the insulating bonding parts 112 contain a filler 115 to such an extent that does not deteriorate the insulation performance. The filler 115 herein may be a metal filler made of, for example, copper or aluminum powder, or an inorganic filler. The inorganic filler is preferably a filler having high radiation performance, such as a ceramic filler made of, for example, boron oxide, alumina, silicon nitride or aluminum nitride. Inclusion of the filler 115 enables improvement in heat transfer performance and adjustment of the thermal expansion of the insulating bonding parts 112.

The diffusion layer 120 is a layer formed by diffusion bonding of the ceramic multilayer substrate 100 and the bonding layer 110. The diffusion layer 120 includes conductive diffusive parts 121 and insulating diffusive parts 122. The conductive diffusive parts 121 are formed by diffusion bonding of the ceramic multilayer substrate 100 and the conductive connectors 111a of the bonding layer 110. The insulating diffusive parts 122 are formed by diffusion bonding of the ceramic multilayer substrate 100 and the insulating bonding parts 112 of the bonding layer 110. Like the insulating bonding parts 112, the insulating diffusive parts 122 may also contain a filler 115. For the purpose of illustration, the boundaries between the conductive diffusive parts 121 and the insulating diffusive parts 122 are clearly shown in FIG. 1. The boundaries between the conductive diffusive parts 121 and the insulating diffusive parts 122 may, however, be unclear.

The semiconductor device 130 includes the electrode pads 131. The electrode pads 131 are made of, for example, gold (Au) as the main constituent. The semiconductor device 130 is arranged on the bonding layer 110 such that the electrode pads 131 are in contact with the conductive connectors 111a of the bonding layer 110. The semiconductor device 130 is electrically connected with the ceramic multilayer substrate 100 via the electrode pads 131 and the conductive connectors 111a (i.e., conductive bonding parts 111).

### A2. Production Method

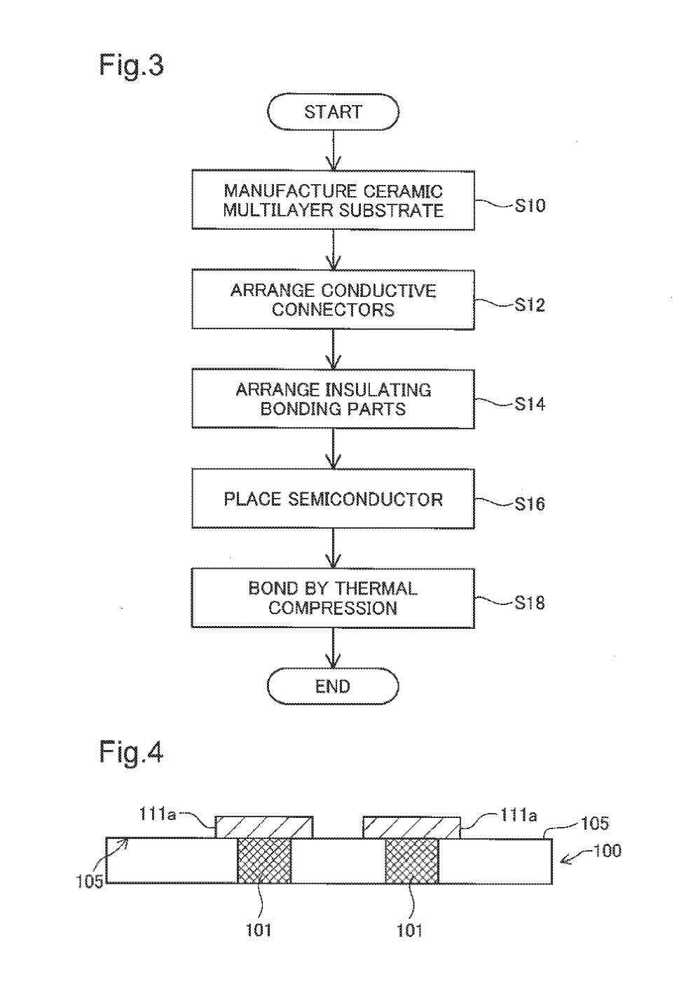

A production method of the semiconductor power module 10 is described with reference to FIGS. 3 to 6. FIG. 3 is a flowchart showing a production method of the semiconductor power module 10 according to the first embodiment.

The procedure manufactures the ceramic multilayer substrate 100 with the inner layer via holes 101 and the interconnecting patterns 109 formed therein (step S10). Manufacturing the ceramic multilayer substrate 100 includes formation of thin-film electrode lands for mounting the semiconductor device 130 and other electronic components on the surface of the ceramic multilayer substrate 100. The electrode lands may be formed by a printing method using a conductive paste, by physical vapor deposition (PVD) or by chemical vapor deposition (CVD). Step S10 of the first embodiment corresponds to the “substrate manufacturing step” of the claims.

The procedure arranges the conductive connectors 111a on the first surface 105 of the ceramic multilayer substrate 100 or specifically at the first regions corresponding to the inner layer via holes 101 (step S12). FIG. 3 illustrates the process of arranging the conductive connectors 111a at step S12. As shown in FIG. 3, metal projections made of, as the main constituent, a metal species which is melted by a subsequent heating process at step S18 described later are formed as the conductive connectors 111a. This metal projection is also called bump. The bumps may be formed by a ball mounting method that arranges metal balls at desired locations and changes to a columnar shape by heating. The bumps may also be formed by a method that transfers a metal constituting bumps at corresponding locations onto the first regions 107 of the first surface 105 of the ceramic multilayer substrate 100 or by a method that prints a paste made of, as the main constituent, the metal species described above as the material of the conductive connectors 111a on the first regions 107 of the first surface 105 of the ceramic multilayer substrate 100 by screen printing. Another applicable method may mask the first regions 107 of the first surface 105 of the ceramic multilayer substrate 100 with a photolithographic pattern and form metal bumps at desired locations by plating.

The procedure subsequently arranges the insulating bonding parts 112 on the first surface 105 of the ceramic multilayer substrate 100 where the conductive connectors 111a have been arranged or specifically at the second regions different from the first regions (step S14). More specifically, the procedure kneads powder glass and a pyrolytic organic binder with a solvent such as an organic solvent or water to produce a glass powder paste and prints the glass powder paste to fill the gaps between the conductive connectors 111a on the first surface 105 of the ceramic multilayer substrate 100 by screen printing.

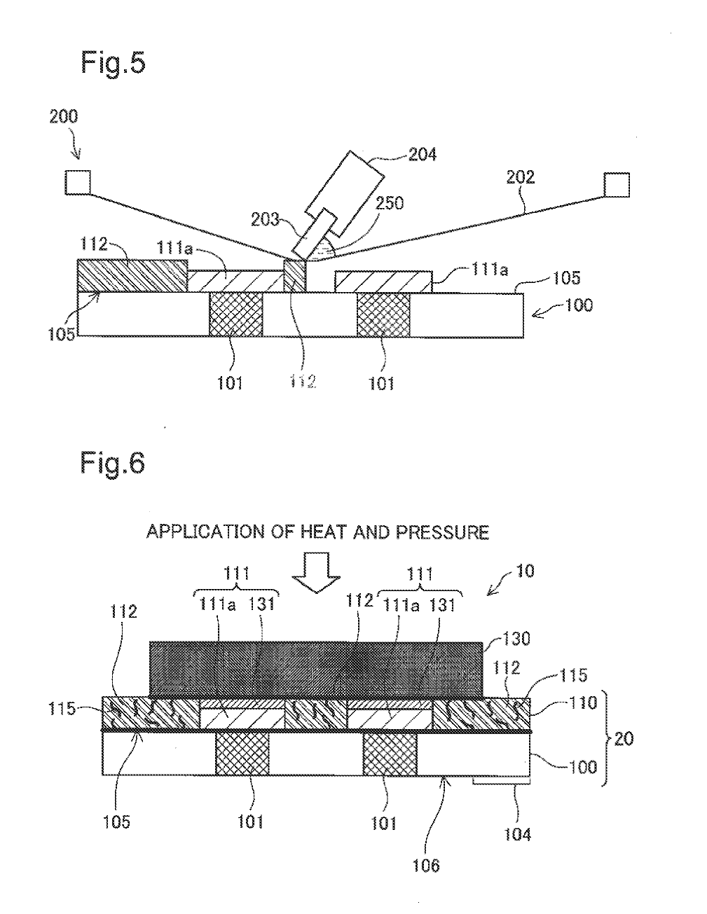

FIG. 5 is a diagram illustrating screen printing of the insulating bonding parts 112 at step S14. A screen printing machine 200 includes a screen 202, a squeegee 203 and a squeegee holder 204. The screen 202 has opening portions created only at residual regions other than regions corresponding to the conductive connectors 111a, i.e., at regions corresponding to the insulating bonding parts 112. A glass powder paste 250 is placed on the screen 202, and the squeegee 203 on the screen 202 is slid. This causes the glass powder paste 250 to pass through the opening portions and to be transferred into residual regions other than regions where the conductive connectors 111a are arranged on the first surface 105 of the ceramic multilayer substrate 100, i.e., regions where the insulating bonding parts 112 are to be arranged. This results in forming a bonding part 110a (FIG. 2) which includes the conductive connectors 111a and the insulating bonding parts 112 and has a planar surface adjoining to the first surface 105 of the ceramic multilayer substrate 100. The order of steps S12 and S14 may be reversed. An organic component (organic binder) used for binding the bonding part 110a is degraded and removed in a heating process described later. In the first embodiment, either step S12 or step S14 may be performed first. Steps S12 and S14 of the first embodiment correspond to the “first placement step” of the claims.

The procedure places the semiconductor device 130 on the formed bonding part 110a (step S16). More specifically, the semiconductor device 130 is arranged, such that the electrode pads 131 are fit in the recesses formed by the conductive connectors 111a and the insulating bonding parts 112. The contact between the conductive connectors 111a and the electrode pads 131 ensures electrical continuity between the semiconductor device 130 and the conductive connectors 111a. Step S16 of the first embodiment corresponds to the “second placement step” of the claims.

The procedure bonds together the ceramic multilayer substrate 100, the bonding layer 110 and the semiconductor device 130 by thermal compression to produce a semiconductor power module (step S18). FIG. 6 is a diagram illustrating the bonding process of the semiconductor power module 10 according to the first embodiment. As shown in FIG. 6, this process applies pressure to and simultaneously heats the ceramic multilayer substrate 100, the bonding layer 110 and the semiconductor device 130 to a temperature that enables thermal fusion bonding between the conductive connectors 111a and the insulating bonding parts 112. This melts the conductive connectors 111a, the insulating bonding parts 112, the first surface 105 of the ceramic multilayer substrate 100 and the surface of the semiconductor device 130 including the conductive bonding parts 111 and an insulating protective film and makes diffusion bonding between the ceramic multilayer substrate 100 and the bonding layer 110 and between the bonding layer 110 and the semiconductor device 130 via void-free uniform planes. Heating to the temperature that enables thermal fusion bonding between the conductive connectors 111a and the insulating bonding parts 112 is, for example, heating to a temperature of 670° C. that enables thermal fusion bonding between both materials when metal aluminum having a melting point of 660° C. is employed as the material of the conductive connectors 111a and ZnO—B₂O₃—SiO₂ glass having a softening point of 640° C. is employed as the material of the insulating bonding parts 112. Step S18 of the first embodiment corresponds to the “bonding step” of the claims.

As described above, application of pressure and heat based on a temperature profile set to enable at least two-step temperature change causes diffusion of atoms at the interface between the ceramic multilayer substrate 100 and the bonding layer 110 to form the diffusion layer 120 and thereby bonds the ceramic multilayer substrate 100 to the bonding layer 110.

In a section cut in a direction orthogonal to the ceramic multilayer substrate 100, the bonding layer 110 and the semiconductor device 130 (stacking direction of the ceramic multilayer substrate 100, the bonding layer 110 and the semiconductor device 130), the interface between the bonding layer 110 and the semiconductor device 130 including a compound semiconductor and a surface protective layer and the interface between the bonding layer 110 and the surface of the ceramic multilayer substrate 100 made of a ceramic component (e.g., alumina, silicon nitride or aluminum nitride) are respectively arranged to be approximately linear as shown by the thick solid line in FIG. 6. No minute defects such as gas bubbles are included in the respective interfaces. Inevitable voids in the order of microns are, however, not included in the defects of the embodiment. According to the embodiment, the size of gas bubbles identified as defects may be, for example, not less than 100 μm.

In the microscopic sense, the above respective interfaces have the diffusion layers 120 formed by diffusion of the structural components of the bonding layer 110 into the semiconductor device 130 and the ceramic multilayer substrate 100. These diffusion layers are defined as layers respectively including a mixed layer with surface components of the semiconductor device 130 (components constituting the protective film, e.g., Zr and Ti) and a mixed layer with the ceramic component of the ceramic multilayer substrate 100 (e.g., aluminum and nitrogen) by mapping analysis, for example, EDS or EPMA.

In the semiconductor power module 10 of the first embodiment described above, the bonding layer 110 is made planar. More specifically, the surface of the bonding layer 110 opposed to the ceramic multilayer substrate 100 is made planar along the shape of the first surface 105 of the ceramic multilayer substrate 100. The other surface of the bonding layer 110 opposed to the semiconductor device 130 is also made planar along the shape of the bonding layer 110-side surface of the semiconductor device 130. In the process of bonding the ceramic multilayer substrate 100 to the semiconductor device 130, this reduces the occurrence of voids between the ceramic multilayer substrate 100 and the bonding layer 110 and voids between the bonding layer 110 and the semiconductor device 130. Accordingly this improves the heat diffusion performance from the semiconductor device 130 to the ceramic multilayer substrate 100 and the bond strength between the ceramic multilayer substrate 100 and the semiconductor device 130.

In the ceramic multilayer substrate 100 of the first embodiment, the insulating bonding parts 112 of the bonding layer 110 are made of, as the main constituent, an inorganic material such as glass having the higher thermal conduction performance than those of organic materials. This configuration improves the heat diffusion performance from the semiconductor device 130 to the ceramic multilayer substrate 100.

Heating in the bonding process of the semiconductor power module 10 (process at step S18 in FIG. 3) causes thermal expansion of the respective members, so that stresses are generated between the ceramic multilayer substrate 100 and the bonding layer 110 and between the bonding layer 110 and the semiconductor device 130. According to the first embodiment, the coefficient of linear thermal expansion of the glass component as the main constituent of the insulating bonding parts 112 is closer to the coefficients of linear thermal expansion of the ceramic multilayer substrate 100 and of the semiconductor device 130 than the coefficient of linear thermal expansion of the metal as the main constituent of the conductive connectors 111a. Accordingly, the stresses generated on the boundaries between the conductive connectors 111a and the ceramic multilayer substrate 100 and between the conductive connectors 111a and the semiconductor device 130 become greater than the stresses generated on the boundaries between the insulating bonding parts 112 and the ceramic multilayer substrate 100 and between the insulating bonding parts 112 and the semiconductor device 130.

In the semiconductor power module 10 of the first embodiment, the insulating bonding parts 112 are located in the periphery of the conductive connectors 111a, so that deformation of the conductive connectors 111a is reduced by the insulating bonding parts 112. The stresses generated between the conductive connectors 111a and the ceramic multilayer substrate 100 and between the conductive connectors 111a and the semiconductor device 130 can thus be dispersed over the interfaces between the conductive connectors 111a and the insulating bonding parts 112. This configuration accordingly enables dispersion of the stresses generated in a concentrated manner between the bonding layer 110 and the ceramic multilayer substrate 100 and between the bonding layer 110 and the semiconductor device 130, thus reducing damage of the semiconductor power module 10 and improving the reliability of the semiconductor power module 10.

In the semiconductor power module 10 of the first embodiment, the diffusion layer 120 is formed between the ceramic multilayer substrate 100 and the bonding layer 110 in the course of diffusion bonding of the ceramic multilayer substrate 100 with the bonding layer 110. This accordingly improves the bond strength between the ceramic multilayer substrate 100 and the bonding layer 110.

In the semiconductor power module 10 of the first embodiment, the filler 115 having the heat transfer performance and the radiation performance is contained in the insulating bonding parts 112 of the bonding layer 110 and in the insulating diffusive parts 122 of the diffusion layer 120. This improves the heat diffusion performance from the semiconductor device 130 to the ceramic multilayer substrate 100.

### B. Second Embodiment

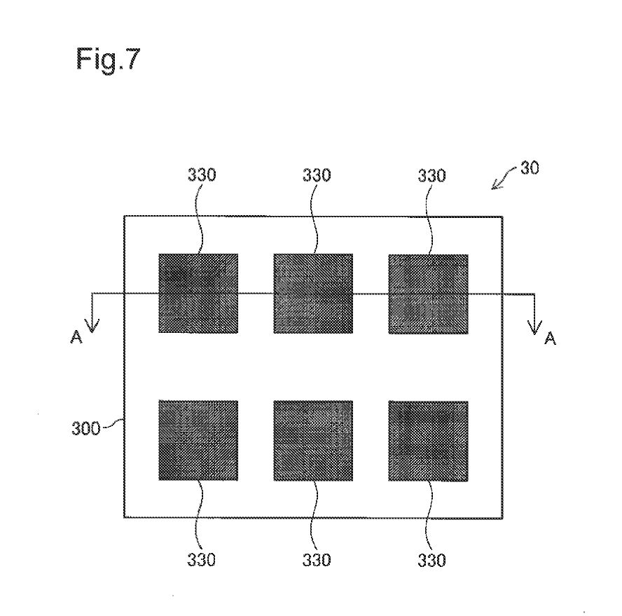

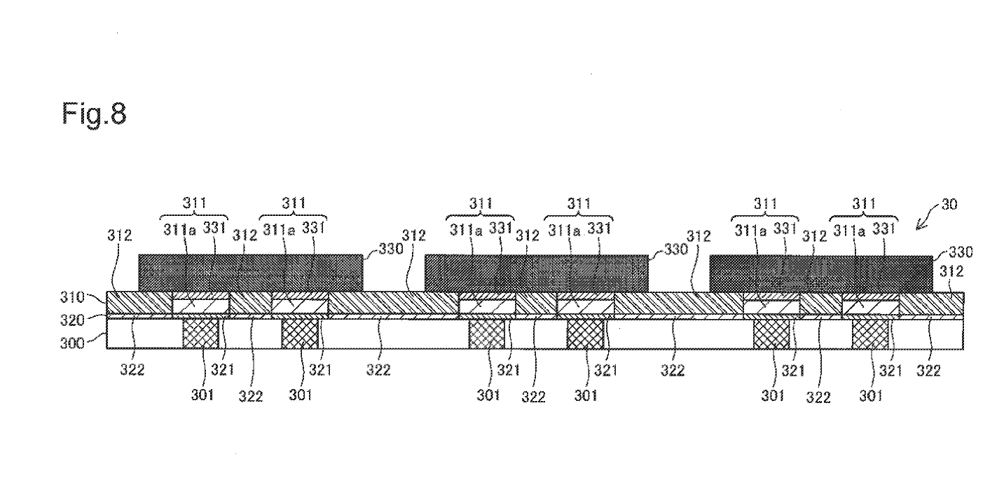

The first embodiment describes the semiconductor power module with only one semiconductor device 130 mounted thereon. A second embodiment describes a semiconductor power module with a plurality of semiconductor devices mounted thereon, with reference to FIGS. 7 and 8.

### B1. Schematic Configuration of Semiconductor Power Module

FIG. 7 is a plan view illustrating a semiconductor power module 30 according to the second embodiment. FIG. 8 is a cross sectional view illustrating the semiconductor power module 30 of the second embodiment. FIG. 8 shows a cross section, taken on the line A-A in FIG. 7.

As shown in FIGS. 7 and 8, the semiconductor power module 30 of the second embodiment includes a ceramic multilayer substrate 300, a bonding layer 310, a diffusion layer 320 and a plurality of (six in the second embodiment) semiconductor devices 330. The bonding layer 310 includes conductive bonding parts 311, each including a conductive connector 311a and an electrode pad 331 of the semiconductor device 330, and insulating bonding parts 312. The diffusion layer 320 includes conductive diffusive parts 321 and insulating diffusive parts 322. The ceramic multilayer substrate 300, the bonding layer 310, the conductive bonding parts 311, the insulating bonding parts 312, the diffusion layer 320, the conductive diffusive parts 321, the insulating diffusive parts 322 and each of the semiconductor devices 330 of the second embodiment respectively have the same configurations as those of the ceramic multilayer substrate 100, the bonding layer 110, the conductive bonding parts 111, the insulating bonding parts 112, the diffusion layer 120, the conductive diffusive parts 121, the insulating diffusive parts 122 and the semiconductor device 130 of the first embodiment.

In general, in response to an increase in allowable amount of heat generation of the semiconductor device accompanied with a change from the conventional Si semiconductor device to the compound semiconductor device such as SiC, the semiconductor device is required to have high heat resistance to the peripheral members. In response to a demand for downsizing of a radiator component as a module, on the other hand, the semiconductor device is required to have high heat diffusivity. In the semiconductor power module 30 of the second embodiment, the bonding layer 310 is made planar, so that the semiconductor devices 330 and the ceramic multilayer substrate 300 are bonded to each other not via an organic material having low heat resistance and heat diffusion properties but via a plane made of, as the main constituent, an inorganic material having excellent heat resistance and heat diffusion properties. This accordingly improves the heat diffusion performance from the semiconductor devices 330 to the ceramic multilayer substrate 300 and thereby provides the semiconductor power module 30 of the high reliability with a plurality of compound semiconductor devices (semiconductor devices 330), which are usable in a high temperature range of or above about 300° C., mounted at the high density.

### C. Third Embodiment

According to a third embodiment, conductive bonding parts have a first bonding start temperature which is a temperature to start bonding conductive connectors to electrode pads of a semiconductor device. Insulating bonding parts have a second bonding start temperature which is a temperature to start bonding to an interconnecting substrate and to a semiconductor device and is higher than the first bonding start temperature. In the third embodiment, except such bonding start temperatures, the conductive bonding parts and the insulating bonding parts constituting the bonding layer have the similar effects and functions to those of the first embodiments and are thus described by using the same numerical symbols (i.e., bonding layer 110, conductive bonding parts 111, conductive connectors 111a, electrode pads 131 and insulating bonding parts 112).

### C1. Bonding Layer

The conductive bonding parts 111 of the bonding layer 110 have a first bonding start temperature which is a temperature to start bonding the conductive connectors 111a to the electrode pads 131. The first bonding start temperature is equal to or higher than a sintering start temperature at which at least a portion of the material constituting the conductive connectors 111a or constituting the electrode pads 131 starts a sintering reaction. The sintering start temperature means a temperature at which the sintering reaction starts, due to formation of a liquid phase by at least a portion of the components constituting the conductive connectors 111a or the electrode pad 131 or due to a reaction on an adhesive interface in a solid phase. The reason why the first bonding start temperature is set to be equal to or higher than the sintering start temperature is attributed to the following. Even when the conductive bonding parts 111 are not melted, sintering adhesion proceeds accompanied with formation of a liquid phase by only a small portion of the components, so as to start bonding members with each other.

According to the third embodiment, the conductive connectors 111a are made of tin, and the electrode pads 131 are made of copper or tin as the material. The temperature at which diffusion bonding proceeds with melting and softening the conductive connectors 111a and the electrode pads 131, for example, 300° C., is set to the first bonding start temperature.

The insulating bonding parts 112 have a second bonding start temperature which is a temperature to start bonding the insulating bonding parts 112 to the ceramic multilayer substrate 100 and to the semiconductor device 130 and is higher than the first bonding start temperature. The second bonding start temperature is equal to or higher than a sintering start temperature at which at least a portion of the material constituting the insulating bonding parts 112 starts a sintering reaction. The temperature at which at least a portion of the material constituting the insulating bonding parts 112 starts a sintering reaction means a temperature at which the sintering reaction starts, due to formation of a liquid phase by at least a portion of the components constituting the insulating bonding parts 112 or due to a reaction on an adhesive interface in a solid phase. The reason why the second bonding start temperature is set to be equal to or higher than the sintering start temperature is attributed to the following. Even when the insulating bonding parts 112 are not melted, sintering adhesion proceeds accompanied with formation of a liquid phase by only a small portion of the components, so as to start bonding to other members.

According to the third embodiment, the insulating bonding parts 112 are made of powder glass composed of Bi₂O₃ and B₂O₃ (softening point: 357° C.). The temperature which is higher than the first bonding start temperature (300° C.) and enables diffusion bonding to sufficiently proceed with softening the insulating bonding parts 112, for example, 450° C., is set to the second bonding start temperature.

### C2. Production Method

The third embodiment employs a temperature profile having a stepwise temperature change and bonds together the ceramic multilayer substrate 100, the bonding layer 110 and the semiconductor device 130 by a diffusion bonding process allowing multi-step bonding. The outline of the production method of the semiconductor power module 10 is similar to the procedure of FIG. 3 described in the first embodiment, except a diffusion bonding process by thermal compression at step S18. The diffusion bonding process at step S18 is described below.

In the third embodiment, after the processing flow to step S16 described above with reference to FIG. 3, the procedure makes diffusion bonding of the ceramic multilayer substrate 100, the bonding layer 110 and the semiconductor device 130 by thermal compression to produce a semiconductor power module (step S18, FIG. 3). According to the third embodiment, this thermal compression process applies heat based on the temperature profile set to allow a multi-step change in heating temperature for diffusion bonding, while applying pressure to the ceramic multilayer substrate 100, the bonding layer 110 and the semiconductor device 130. The diffusion bonding process including the heating process based on the temperature profile includes maintaining the heating temperature at the first bonding start temperature for a specified time (first bonding step) and subsequently maintaining the heating temperature at the second bonding start temperature for a specified time (second bonding step). The procedure of the third embodiment uses a pressing jig having a slightly smaller area than the rear face area of the semiconductor device 130 to press the semiconductor device 130 against the ceramic multilayer substrate 100. The first bonding step and the second bonding step are described more specifically below.

The first bonding step performs the heating process by maintaining the heating temperature at the first bonding start temperature (300° C.) for a specified time (for example, about 10 minutes), so that diffusion bonding proceeds between the conductive connectors 111a and the electrode pads 131, so as to form the conductive bonding parts 111. Since the softening point of the insulating bonding parts 112 (357° C.) is higher than the first bonding start temperature, the insulating bonding parts 112 are not softened in the first bonding step. The material constituting the insulating bonding parts 112 accordingly does not enter between the conductive connectors 111a and the electrode pads 131, so that the material constituting the insulating bonding parts 112 is not mixed into the conductive bonding parts 111 formed by diffusion bonding of the conductive connectors 111a and the electrode pads 131.

When the diffusion bonding between the conductive connectors 111a and the electrode pads 131 sufficiently proceeds to allow integration of the conductive connectors 111a with the electrode pads 131, the second bonding step starts. The second bonding step performs the heating process at the second bonding start temperature (450° C.). The heating process sufficiently melts and softens the insulating bonding parts 112, the first surface 105 of the ceramic multilayer substrate 100 and the surface of the semiconductor device 130 made of an insulating protective film. Diffusion bonding proceeds with deforming the softened insulating bonding parts 112 to fill the gaps between the semiconductor device 130 and the bonding layer 110 and the gaps between the bonding layer 110 and the ceramic multilayer substrate 100 by the pressing force of the pressing jig that presses the semiconductor device 130 against the ceramic multilayer substrate 100. As a result, diffusion bonding is made via void-free uniform planes between the ceramic multilayer substrate 100 and the insulating bonding parts 112 and between the insulating bonding parts 112 and the surface of the semiconductor device 130. As described above, this completes production of the semiconductor power module 10.

In the semiconductor power module of the third embodiment described above, the process of forming the conductive bonding parts employs, as the heating temperature, the first bonding start temperature that is lower than the temperature at which the insulating bonding parts start the sintering reaction, so that the conductive bonding parts are bonded, prior to the insulating bonding parts. Accordingly, in the state that the conductive connectors 111a are bonded to the electrode pads 131 of the semiconductor device and that the conductive bonding parts 111 are bonded to the ceramic multilayer substrate 100, i.e., in the state that there is substantially no void between the conductive connectors 111a and the electrode pads 131 of the semiconductor device and between the conductive bonding parts 111 and the ceramic multilayer substrate 100, the insulating bonding parts 112 start softening and deforming, so as to bond the insulating bonding parts 112 to the semiconductor device 130 and bond the insulating bonding parts 112 to the ceramic multilayer substrate 100. This configuration suppresses deterioration of the conductive performance of the conductive bonding parts 111 due to invasion of the material constituting the insulating bonding parts 112 between the conductive connectors 111a and the electrode pads 131, i.e., mixing of the material constituting the insulating bonding parts 112 into the conductive bonding parts 111.

In the semiconductor power module of the third embodiment, the first bonding start temperature is the melting start temperature of the material constituting the conductive bonding parts, and the second bonding start temperature is the melting start temperature of the material constituting the insulating bonding parts. Accordingly this configuration ensures the conductive bonding parts and the insulating bonding parts to be melted, thus improving the bond strength between the respective conductive bonding parts and insulating bonding parts with other members.

### D. Fourth Embodiment

### D1. Schematic Configuration of Semiconductor Power Module

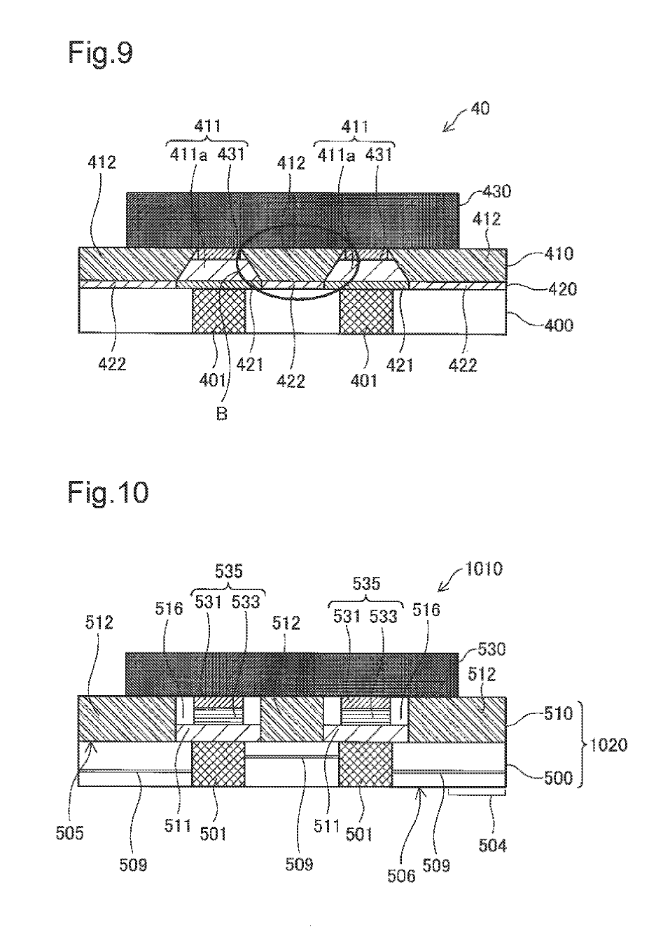

FIG. 9 is a cross sectional view illustrating a semiconductor power module 40 according to a fourth embodiment. As shown in FIG. 9, like the semiconductor power module 10 of the first embodiment, the semiconductor power module 40 of the fourth embodiment includes a ceramic multilayer substrate 400, a bonding layer 410 and a diffusion layer 420. The diffusion layer 420 includes conductive diffusive parts 421 and insulating diffusive parts 422. The ceramic multilayer substrate 400, the diffusion layer 420, the conductive diffusive parts 421, the insulating diffusive parts 422 and a semiconductor device 430 of Modification 1 respectively have the same configurations as those of the ceramic multilayer substrate 100, the diffusion layer 120, the conductive diffusive parts 121, the insulating diffusive parts 122 and the semiconductor device 130 of the first embodiment.

The semiconductor power module 40 of the fourth embodiment differs in configuration of the bonding layer 410 from the semiconductor power module 10 of the first embodiment. The bonding layer 410 is provided as a planar thin film and includes conductive bonding parts 411, each including a conductive connector 411a and an electrode pad 431 of the semiconductor device 430, and insulating bonding parts 412. The insulating bonding parts 412 are formed in a tapered shape to have a wider area on the semiconductor device 430-side surface than the area on the ceramic multilayer substrate 400-side surface as shown by encirclement B in FIG. 9. The conductive connector 411a is formed in a specific shape corresponding to the tapered shape of the insulating bonding parts 412. The shape of the insulating bonding parts 412 is, however, not limited to the tapered shape but may be any shape having a wider area on the semiconductor device 430-side surface than the area on the ceramic multilayer substrate 400-side surface, for example, a stepped shape or a curved shape.

The semiconductor power module 40 may be produced by the similar method to the method of producing the semiconductor power module 10 of the first embodiment, except the process of arranging the bonding layer 410 (corresponding to steps S12 and S14 in FIG. 3). The process of arranging the bonding layer 410 according to the fourth embodiment may employ, for example, the following procedure.

The procedure arranges the insulating bonding parts 412, prior to the conductive connectors 411a, by screen printing. More specifically, the procedure uses a screen with opening portions in a tapered shape having a wider area on the semiconductor device 430-side and prints a glass powder paste as the material of the insulating bonding parts 412.

The procedure subsequently uses a screen with opening portions at the regions corresponding to the conductive connectors 411a and prints a paste made of, as the main constituent, a metal species as the material of the conductive connectors 411a. The viscosity of the paste used is adjusted, so that the paste is spread over the wider area on the semiconductor device 430-side than the surface of the opening portions by the dead weight of the paste after application of the paste on the semiconductor device 430. This completes the bonding parts including the insulating bonding parts 412 in the tapered shape and the conductive connectors 411a in the specific shape corresponding to the tapered shape of the insulating bonding parts 412. The procedure then places the semiconductor device 430 such that the electrode pads 431 of the semiconductor device 430 are fit in the recesses formed by the conductive connectors 411a and the insulating bonding parts 412. This forms the planar bonding layer 410.

In the semiconductor power module 40 of the fourth embodiment, the insulating bonding parts 412 of the bonding layer 410 are formed in the tapered shape having the wider area on the semiconductor device 430-side surface than the area on the ceramic multilayer substrate 100-side surface. Compared with the insulating bonding parts 112 of the first embodiment, this configuration provides the wider contact area between the insulating bonding parts 412 and the semiconductor device 430. This accordingly improves the heat diffusion performance from the semiconductor device 430 to the bonding layer 410, compared with the semiconductor power module 10 of the first embodiment. This improves the heat diffusion performance and accelerates heat radiation of the semiconductor device 430, while ensuring the insulation performance between the ceramic multilayer substrate 400 and the semiconductor device 430.

### E. Fifth Embodiment

### E1. Schematic Configuration of Semiconductor Power Module

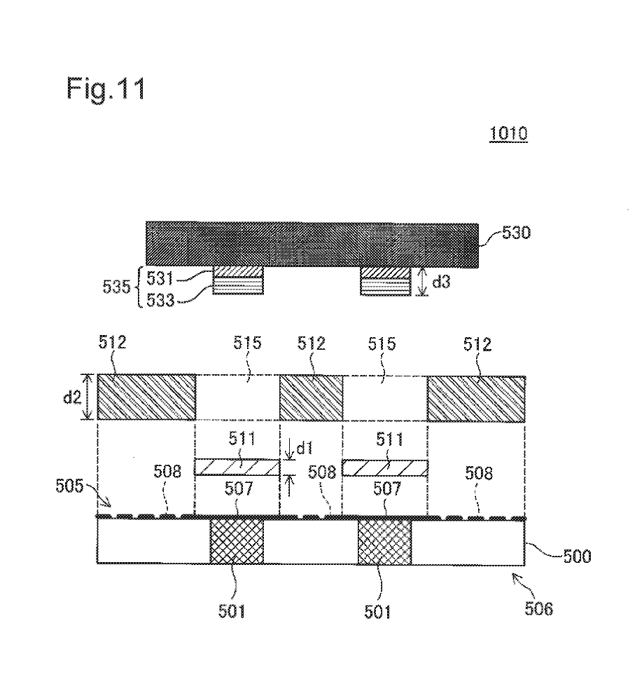

FIG. 10 is a cross sectional view illustrating the schematic configuration of a semiconductor power module 1010 according to a fifth embodiment. FIG. 11 is a diagram illustrating the semiconductor power module 1010 of the fifth embodiment. The semiconductor power module 1010 includes a ceramic multilayer substrate 500, a bonding layer 510 and a semiconductor device 530.

The ceramic multilayer substrate 500 is made of a ceramic material. As the ceramic material used may be, for example, aluminum oxide (Al₂O₃), aluminum nitride (AlN) or silicon nitride (Si₃N₄). The ceramic multilayer substrate 500 includes a first surface 505 with a semiconductor device mounted thereon, inner layer via holes 501 each arranged to electrically connect the first surface 505 with the other surface or a second surface 506 opposed to the first surface 505 and configured to mount other electronic components such as a control circuit and a capacitor, interconnecting patterns 509 and an electrode terminal 504 for external connection placed on the second surface 506. The interconnecting patterns 509 are formed on the surfaces of the ceramic multilayer substrate 500 and the surfaces of inner layers. The interconnecting patterns formed on the surfaces of the ceramic multilayer substrate 500 are omitted from illustration of FIG. 10. Electrode lands (not shown) for mounting the semiconductor device 530 and other electronic components are formed on the first surface 505 and the second surface 506 of the ceramic multilayer substrate 500. The semiconductor device 530 is electrically connected with the electrode terminal 504 placed on the second surface 506 via the inner layer via holes 501 and the interconnecting patterns 509.

The bonding layer 510 is placed on the first surface 505 of the ceramic multilayer substrate 500 and is provided as a thin film layer including conductive connectors 511, an insulating bonding part 512 and projections 535 of the semiconductor device 530 described later. The bonding layer 510 has a smooth surface on the first surface 505-side. In the description of the embodiment, the state without the projections 535 is also described as the bonding layer 510. The projections 535 of the fifth embodiment correspond to the “protruded part” of the claims. The same applies to a sixth embodiment described later.

The insulating bonding part 512 isolates the semiconductor device 530 from the ceramic multilayer substrate 500. As shown in FIG. 11, the insulating bonding part 512 is arranged on the first surface 505 of the ceramic multilayer substrate 500, and opening portions 515 are created at regions 507 (shown by the thick solid line) corresponding to the inner layer via holes 501. In other words, the insulating bonding part 512 is arranged on the first surface 505 of the ceramic multilayer substrate 500 to be placed at regions 508 (shown by the thick broken line) other than the regions 507 corresponding to the inner layer via holes 501. The insulating bonding part 512 is made of a glass composition including an insulating inorganic material as the main constituent. The insulating inorganic material may be, for example, silicon oxide or zinc oxide.

The conductive connectors 511 electrically connect the semiconductor device 530 with the ceramic multilayer substrate 500. The conductive connectors 511 are placed in the opening portions 515 on the first surface 505 of the ceramic multilayer substrate 500 as shown in FIG. 11. In other words, the conductive connectors 511 are located at the regions 507 corresponding to the inner layer via holes 501. The conductive connectors 511 are made of, as the main constituent, a conductive metal. The conductive metal may be, for example, copper, silver or metal aluminum. The conductive connectors 511 have at least planar interfaces with the first surface 505.

As shown in FIG. 10, the bonding layer 510 also has recesses 516 formed by the conductive connectors 511 and the insulating bonding part 512. The recess 516 has a volume that is equal to greater than the total volume of the metal projection 535 formed on the semiconductor device 530 as described later. It is here assumed that d1 represents the thickness of the conductive connectors 511; d2 represents the thickness of the insulating bonding part 512; d3 represents the height of the projections 535; and d4 represents an allowable variation in height of the projections 535 caused by warpage of the ceramic multilayer substrate 500 as shown in FIGS. 10 and 11. The height d3 of the projections 535 is designed to be greater than the sum of d4 and the height (d2−d1) of the recesses 516 formed by the insulating bonding part 512 and the conductive connectors 511, i.e., to satisfy d3≧(d2−d1)+d4.

The ceramic multilayer substrate 500 may have little warpage during manufacture. When the height of the recesses 516 in the thickness direction is equal to the height of the projections 535 in the thickness direction, the effect of such little warpage of the ceramic multilayer substrate 500 may cause a clearance between a recess 516-side end of the projection 535 and the opposed recess 516. This may result in poor electrical connection between the projections 535 and the conductive connectors 511. Determining the height of the recesses 516 in the thickness direction by taking into account the height variation d4 in the thickness direction of the ceramic multilayer substrate 500, i.e., satisfying d3>d2−d1, ensures the good electrical connection between the projections 535 and the conductive connectors 511 when the semiconductor device 530 is set in the recesses 516. Even when the ceramic multilayer substrate 500 has little warpage, this configuration allows for a height variation of the interface equal to or less than d3−(d2−d1).

For the purpose of illustration, d1 and d2 are simply expressed as thicknesses in the above description. The thicknesses of the conductive connectors 511 and the insulating bonding part 512 may, however, not be completely uniform. This may result in a variation in thickness according to the measurement position. Additionally, the projections 535 of the semiconductor device 530 are not necessarily made planar as described in the fifth embodiment but may be formed, for example, in a spherical shape. Accordingly, d1 to d3 may be defined as follows: d1 may represent a maximum value of the distance from the first surface 505 of the ceramic multilayer substrate 500 to the semiconductor device 530-side surface of the conductive connector 511; d2 may represent a maximum value of the distance from the first surface 505 of the ceramic multilayer substrate 500 to the semiconductor device 530-side surface of the insulating bonding part 512; and d3 may represent a maximum value of the height of the projection 535 in the stacking direction from the interface between the semiconductor device 530 and the bonding layer 510.

The semiconductor device 530 has the projections 535 as described above. The projection 535 includes an electrode pad 531 and a metal bump 533. The electrode pads 531 are made of, for example, gold (Au) as the main constituent. The bumps 533 are formed to be protruded on the electrode pads 531. The bumps 533 may be formed by arranging metal columns processed in a bump shape at desired locations. The bumps 533 may also be formed by transferring a paste made of a metal specifies such as metal aluminum or silver oxide as the main constituent onto the electrode pads 531 by using a photolithographic pattern or by screen printing the paste.

The semiconductor device 530 is arranged on the bonding layer 510, such that the projections 535 are received in the recesses 516. When the semiconductor device 530, the ceramic multilayer substrate 500 and the bonding layer 510 are integrally bonded by application of heat and pressure, the ceramic multilayer substrate 500 and the semiconductor device 530 are electrically connected with each other via the conductive connectors 511 and the projections 535 or specifically the bumps 533 and the electrode pads 531. For the purpose of illustration, the bumps 533 and the conductive connectors 511 are illustrated with no change in shape before and after such bonding in the respective drawings. The bumps 533 and the conductive connectors 511 are, however, deformed by application of heat in the bonding process to fill the cavities of the recesses 516, so that the interface between the insulating bonding part 512 and the semiconductor device 530 is made planar. The difference between the volume of the recess 516 and the volume of the projection 535 shown in FIG. 10 is smaller than the volume of the recess 516 prior to integration with the semiconductor device 530. The bond strength between the semiconductor device 530 and the ceramic multilayer substrate 500 is provided by the insulating bonding part 512, in addition to the projections 535 and the conductive connectors 511. The stress caused by the difference in thermal expansion among the respective members by the heat generated during operation of the semiconductor device 530 is dispersed over the conductive connectors 511 and the insulating bonding part 512. This results in improving the endurance reliability of the semiconductor module. The heat generated during operation of the semiconductor device 530 is diffused to the ceramic multilayer substrate 500 via the projections 535 and the conductive connectors 511, while being diffused to the ceramic multilayer substrate 500 via the insulating bonding part 512. This results in suppressing a temperature increase of the semiconductor device.

It is preferable that the projections 535 and the recesses 516 are formed such that the volume of the projection 535 is substantially equal to the volume of the recess 516. As long as electrical connection is made, the volume of the recess 516 may be greater than the volume of the projection 535.

### E2. Production Method

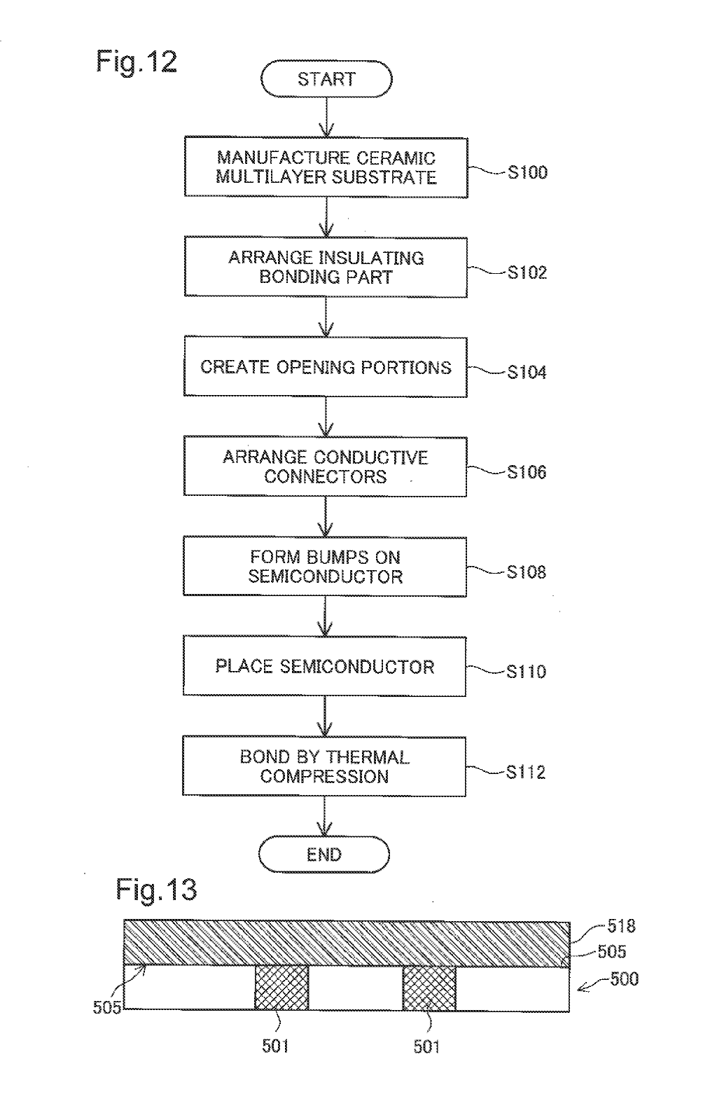

A production method of the semiconductor power module 1010 is described with reference to FIGS. 12 to 16. FIG. 12 is a flowchart showing a production method of the semiconductor power module 1010 according to the fifth embodiment.

The procedure manufactures the ceramic multilayer substrate 500 with the inner layer via holes 501 and the interconnecting patterns 509 formed therein (step S100). Manufacturing the ceramic multilayer substrate 500 includes formation of thin-film electrode lands for mounting the semiconductor device 530 and other electronic components on the surface of the ceramic multilayer substrate 500. The electrode lands may be formed by a printing method using a conductive paste, by physical vapor deposition (PVD) or by chemical vapor deposition (CVD). Step S100 of the fifth embodiment corresponds to the “substrate manufacturing step” of the claims.

The procedure subsequently arranges the insulating bonding part 512 on the first surface 505 of the manufactured ceramic multilayer substrate 500 (step S102). The process of arranging the insulating bonding part 512 is described with reference to FIG. 13.

FIG. 13 is a diagram illustrating the process of arranging the insulating bonding part 512 at step S102. The procedure kneads powder glass as the main constituent of the insulating bonding part 512 and a pyrolytic organic binder with a solvent such as an organic solvent or water to produce a glass powder paste 518 and applies the glass powder paste 518 on the first surface 505 of the ceramic multilayer substrate 500 as shown in FIG. 13.

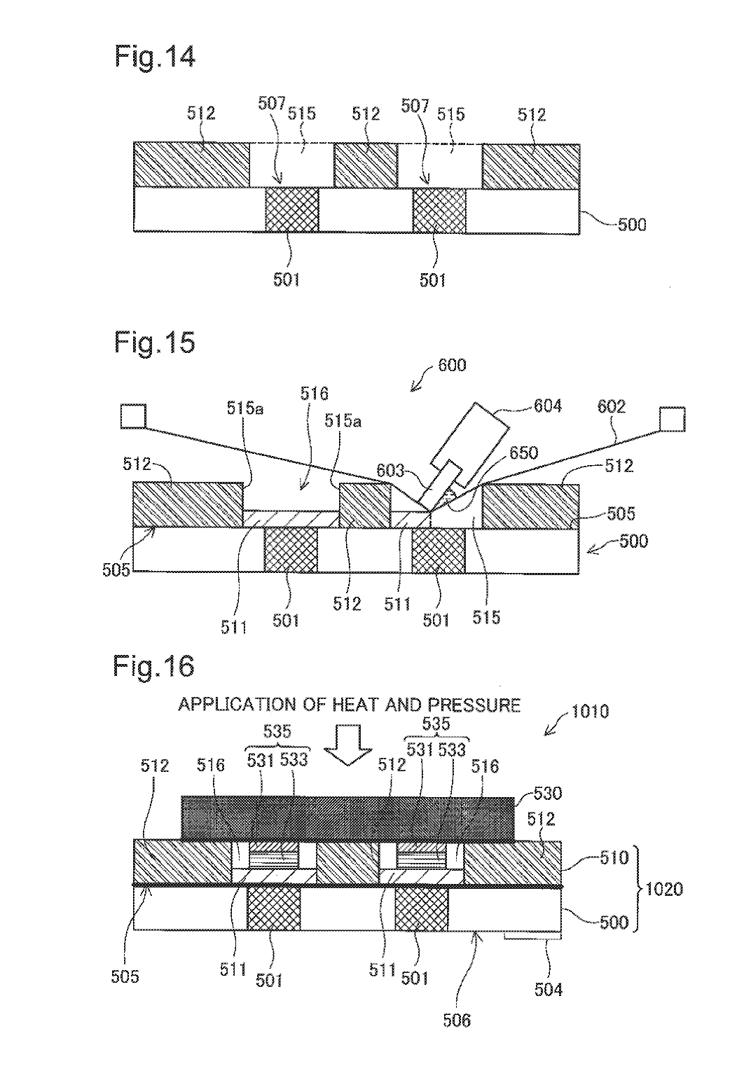

The procedure then creates the opening portions 515 in the insulating bonding part 512 formed on the ceramic multilayer substrate 500 (step S104). The process of creating the opening portions 515 is described with reference to FIG. 14.

FIG. 14 is a diagram illustrating the process of creating the opening portions 515 at step S104. The ceramic multilayer substrate 500 with the glass powder paste (insulating bonding part 512) applied thereon is subjected to heat treatment at a specific temperature that causes thermal decomposition of resist (for example, 700° C. or higher) and is lower than the softening point of the glass powder (for example, 600° C. or lower), so that the opening portions 515 are created at the regions 507 corresponding to the inner layer via holes 501. The aspect of creating the opening portions by processing the paste constituting the insulating bonding part 512 as described in the fifth embodiment is included in the “step that places the insulating bonding part with the opening portions on the first surface” of the claims.

In order to form the recesses 516 which have the greater volume than the volume of the conductive projections 535 formed on the semiconductor device 530, in the opening portions 515 of the insulating bonding part 512, the procedure arranges the conductive connectors 511 which are thinner than the insulating bonding part 512, in the opening portions 515 (step S106). More specifically, the procedure fills a paste made of, as the main constituent, a metal species which is melted by a subsequent heating process at step S112 described later, in part of the opening portions 515 by screen printing. The paste is printed, such that the recesses 516 are formed by the conductive connectors 511 and the insulating bonding part 512.

FIG. 15 is a diagram illustrating the process of arranging the conductive connectors 511 at step S106. A screen printing machine 600 includes a screen 602, a squeegee 603 and a squeegee holder 604. The screen 602 has through holes formed at only the regions 507 corresponding to the inner layer via holes 501, i.e., the regions corresponding to the opening portions 515 created in the insulating bonding part 512. A paste 650 made of a metal as the main constituent is placed on the screen 602, and the squeegee 603 on the screen 602 is slid. This causes the paste 650 to pass through the through holes of the screen and to be transferred into the opening portions 515 of the insulating bonding part 512 on the first surface 505 of the ceramic multilayer substrate 500. When the conductive connectors 511 are placed in the opening portions 515, the recesses 516 are formed by inner circumferential surfaces 515a of the opening portions 515 of the insulating bonding part 512 and opposite surfaces 511a of the conductive connectors 511 opposite to ceramic multilayer substrate 500-side surfaces. Steps S102 to S106 of the fifth embodiment correspond to the “first placement step” of the claims.

The ceramic multilayer substrate 500 and the conductive connectors 511 and the insulating bonding part 512 are temporary stacked (bonded) by the bonding force of the organic binder included in a paste for printing, so that a circuit board 1020 is completed.

The procedure then forms bumps 533 on the electrode pads 531 of the semiconductor device 530 (step S108). The bumps 533 are formed, such that the total volume of the electrode pad 531 and the bump 533 is not greater than the volume of the recess 516. More specifically, the procedure places a metal bump made of a species which is melted by the subsequent heating process at step S110 described later, such as metal aluminum, silver oxide, copper, nanometal or solder alloy, on the electrode pad 531. The bumps may be formed by a ball mounting method that arranges metal balls at desired locations and changes to a columnar shape by heating. The bumps may also be formed by a method that transfers a metal constituting bumps at corresponding locations of the semiconductor device 530, by a method that prints a paste made of, as the main constituent, the metal species described above by screen printing or by a method that uses a photolithographic pattern for masking and forms metal bumps at desired locations by plating.

The procedure then places the semiconductor device 530 on the bonding layer 510, such that the projections 535 of the semiconductor device 530 are received in the recesses 516 of the bonding layer 510 (step S110), and bonds together the ceramic multilayer substrate 500, the bonding layer 510 and the semiconductor device 530 by thermal compression, so as to produce a semiconductor power module (step S112). Steps S108 and S110 of the fifth embodiment correspond to the “second placement step” of the claims, and step S112 corresponds to the “bonding step” of the claims.

FIG. 16 is a diagram illustrating the bonding process of the semiconductor power module 1010 according to the fifth embodiment. As shown in FIG. 16, this process applies pressure to and simultaneously heats the ceramic multilayer substrate 500, the bonding layer 510 and the semiconductor device 530 to a temperature that enables thermal fusion bonding between the conductive connectors 511, the insulating bonding part 512 and the bumps 533. This melts the conductive connectors 511, the insulating bonding part 512 and the first surface 505 of the ceramic multilayer substrate 500 and makes diffusion bonding between the ceramic multilayer substrate 500 and the bonding layer 510 and between the bonding layer 510 and the semiconductor device 530 via void-free uniform planes. Heating to the temperature that enables thermal fusion bonding between the conductive connectors 511 and the insulating bonding part 512 is, for example, heating to a temperature of 670° C. that enables thermal fusion bonding between both materials when metal aluminum having a melting point of 660° C. is employed as the material of the conductive connectors 511 and the bumps 533 and ZnO—B₂O₃—SiO₂ glass having a softening point of 640° C. is employed as the material of the insulating bonding part 512. The process also applies a pressure of about 500 kPa to bond the ceramic multilayer substrate including the bonding layer 510 with the semiconductor device 530 under pressure.

Such application of pressure and heat causes diffusion of atoms at the interface between the ceramic multilayer substrate 500 and the bonding layer 510, so as to bond the ceramic multilayer substrate 500 to the bonding layer 510. Application of heat fuses both the materials of the bumps 533 of the semiconductor device 530 and the conductive connectors 511, so as to bond the bumps 533 to the conductive connectors 511.

In a section cut in a direction orthogonal to the ceramic multilayer substrate 500, the bonding layer 510 and the semiconductor device 530 (stacking direction of the ceramic multilayer substrate 500, the bonding layer 510 and the semiconductor device 530), the interface between the bonding layer 510 and the semiconductor device 530 including a compound semiconductor and a surface protective layer and the interface between the bonding layer 510 and the surface of the ceramic multilayer substrate 500 made of a ceramic component (e.g., alumina, silicon nitride or aluminum nitride) are respectively arranged to be approximately linear as shown by the thick solid line in FIG. 16. No minute defects such as gas bubbles are included in the respective interfaces. Inevitable voids in the order of microns are, however, not included in the defects of the embodiment. According to the embodiment, the size of gas bubbles identified as defects may be, for example, not less than 500 μm.

In the semiconductor power module 1010 of the fifth embodiment described above, with respect to fitting of the projection 535 into the opening portion 515, the conductive connectors 511 and the insulating bonding part 512 are formed to satisfy d3>d2−d1 where d1 represents the thickness of the conductive connectors 511, d2 represents the thickness of the insulating bonding part 512 and d3 represents the thickness of the projections 535 in the stacking direction. Accordingly this ensures the good electrical connection between the projections 535 and the conductive connectors 511 when the semiconductor device 530 is set in the recesses 516.

In the semiconductor power module 1010 of the fifth embodiment, the bonding layer 510 has the recesses 516 having the volume that is equal to or greater than the volume of the projections 535 formed on the semiconductor device 530. When the semiconductor device 530 is mounted on the circuit board 1020, the projections 535 of the semiconductor device are received in the recesses 516, so that the interface between the bonding layer 510 and the semiconductor device 530 is made approximately planar. Additionally, the ceramic multilayer substrate 500 and the bonding layer 510 are bonded to each other via the plane. This reduces the occurrence of voids at the interface between the ceramic multilayer substrate 500 and the bonding layer 510 and at the interface between the bonding layer 510 and the semiconductor device 530. Accordingly this improves the bond strength between the ceramic multilayer substrate 500 and the bonding layer 510 and the heat diffusion performance from the semiconductor device to the ceramic multilayer substrate 500.

### F. Sixth Embodiment

### F1. Schematic Configuration of Semiconductor Power Module

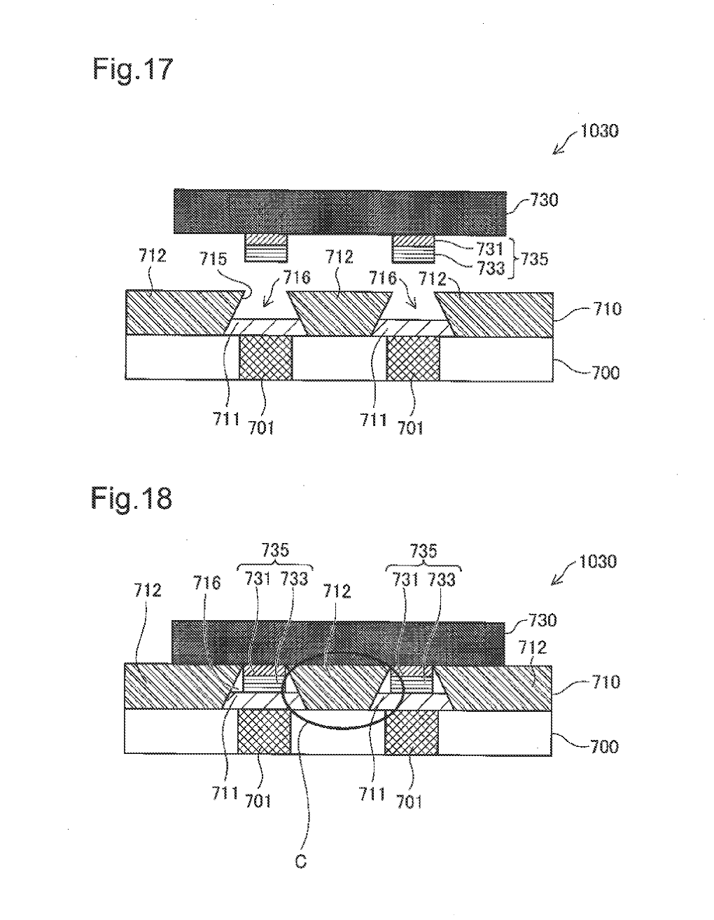

FIGS. 17 and 18 are cross sectional views illustrating the configuration of a semiconductor power module 1030 according to a sixth embodiment. As shown in FIGS. 17 and 18, the semiconductor power module 1030 of the sixth embodiment includes a ceramic multilayer substrate 700, a bonding layer 710 and a semiconductor device 730. The ceramic multilayer substrate 700 and the semiconductor device 730 of the sixth embodiment respectively have the same configurations as those of the ceramic multilayer substrate 500 and the semiconductor device 530 of the fifth embodiment.

The semiconductor power module 1030 differs in configuration of the bonding layer 710 from the semiconductor power module 1010 of the fifth embodiment. The bonding layer 710 includes conductive connectors 711, an insulating bonding part 712 and recesses 716 formed by the conductive connectors 711 and the insulating bonding part 712. The interface between the bonding layer 710 and the ceramic multilayer substrate 700 is made planar.

The insulating bonding part 712 has opening portions 715 created at regions corresponding to inner layer via holes 701 of the ceramic multilayer substrate 700. Each portion of the insulating bonding part 712 is formed in a tapered shape narrowing from a semiconductor device 730-side end toward a ceramic multilayer substrate 700-side end as shown by encirclement C in FIG. 18.

The recesses 716 are formed by placing the conductive connectors 711 in the opening portions 715. The recess 716 has a volume that is equal to or greater than the volume of a projection 735 which consists of an electrode pad 731 of the semiconductor device 730 and a bump 733.

The semiconductor power module 1030 may be produced by the production method of the semiconductor power module 1010 of the fifth embodiment. In order to manufacture the portions in the tapered shape, the insulating bonding part 712 and the conductive connectors 711 may be produced in a plurality of steps. More specifically, the procedure prints a glass powder paste as the material of the insulating bonding part 712 in a thickness less than a desired thickness of the insulating bonding part 712 by using a screen mask. The screen mask used here is provided to mask only the regions corresponding to the opening portions 715. The procedure subsequently forms the conductive bonding parts 711 in the opening portions 715. The procedure repeats this series of processes a plurality of times using a plurality of screen masks having different mask sizes at the regions corresponding to the opening portions, in order to gradually narrow the opening portions formed in the insulating bonding part 712 and eventually form the insulating bonding part 712 of the desired thickness. This completes the insulating bonding part 712 having the opening portions 715 in the tapered shape at the regions corresponding to the inner layer via holes 701.

The procedure forms metal bumps 733 on the electrode pads 731 of the semiconductor device 730. The bumps 733 are formed, such that the total volume of the electrode pad 731 and the bump 733 is equal to or less than the volume of the recess 716. The procedure then places the semiconductor device 730 on the bonding layer 710 such that the projections 735 are received in the recesses 716, and bonds together the ceramic multilayer substrate 700, the bonding layer 710 and the semiconductor device 730 by application of heat and pressure (corresponding to steps S110 and S112 of FIG. 12).

In the semiconductor power module 1030 of the sixth embodiment, each portion of the insulating bonding part 712 of the bonding layer 710 is formed in the tapered shape narrowing from the semiconductor device 730-side toward the ceramic multilayer substrate 500-side. Compared with the insulating bonding part 512 of the fifth embodiment, this configuration ensures the wider contact area between the insulating bonding part 712 and the semiconductor device 730. Accordingly, compared with the semiconductor power module 1010 of the fifth embodiment, this improves the heat diffusion performance from the semiconductor device 730 to the bonding layer 710. This improves the heat diffusion performance and accelerates heat radiation of the semiconductor device 730, while ensuring the insulation performance between the ceramic multilayer substrate 700 and the semiconductor device 730.

The insulating bonding part 712 is formed to have the wider area on the surface that is in direct contact with the semiconductor device 730. This ensures the sufficient bonding area between the semiconductor device 730 and the insulating bonding part 712 without being affected by the filling ratio depending on deformation of the bumps 733 when the semiconductor device 730 is bonded to the ceramic multilayer substrate 700 with the bonding layer 710 formed thereon. This results in ensuring the stable bond strength between the semiconductor device 730 and the ceramic multilayer substrate 700 with no variation between manufacturing lots.

### G. Modifications

### G1. Modification 1

The semiconductor power module 10 may be produced by the following method, in place of the production method of the semiconductor power module 10 (FIG. 3) according to the first embodiment. The following describes a modified procedure, subsequent to step S10. The respective members are expressed by the same numerals and symbols as those of the first embodiment.

The procedure forms an insulating bonding part 112. More specifically the procedure kneads powder glass and a pyrolytic organic binder (for example, butyral binder that is softened at the temperature of about 80° C. and is thermally decomposed at the temperature of about 250° C.) with a solvent such as an organic solvent or water to produce a slurry and molds the slurry in a sheet form by a technique, such as sheet casting according to the doctor blade method or extrusion molding. The procedure subsequently creates through holes at regions corresponding to the conductive bonding parts 111 in the sheet by machining process, such as laser processing or microcomputer punching. In this manner, the insulating bonding part 112 is manufactured as the glass sheet with the through holes.

The procedure places the ceramic multilayer substrate 100, such that the first surface 105 of the ceramic multilayer substrate 100 is opposed to a desired surface of the insulating bonding part 112, and applies heat and pressure to the ceramic multilayer substrate 100 and the insulating bonding part 112 to a temperature equal to or higher than the softening temperature of the organic binder included in the sheet of insulating bonding part, so as to temporary adhere the ceramic multilayer substrate 100 with the insulating bonding part 112 by the binding force of the organic binder included in the sheet of the insulating bonding part 112.

The procedure subsequently forms conductive connectors 111a. More specifically, the procedure fills a paste for forming the conductive connectors 111a into the through holes of the manufactured insulating bonding part 112 by screen printing. The paste is made of a metal as the main constituent and may be produced, for example, by kneading a metal species which is melted by the heating process at step S18 in FIG. 3, such as metal aluminum, silver oxide, copper, nanometal or solder alloy and a pyrolytic organic binder with a solvent such as an organic solvent or water. The technique employed for filling the paste is not limited to screen printing but may be, for example, discharge with a dispenser.

The procedure heats the semiconductor device 130 to a temperature that is equal to or higher than the melting points of the glass and the metal as the main constituents of the insulating bonding part 112 and the conductive connectors 111a, applies pressure to bond the semiconductor device 130 to the ceramic multilayer substrate 100 and the conductive connectors 111a and the insulating bonding part 112 stacked as described above, and removes the organic binder component included in the insulating bonding part 112 by thermal decomposition, so as to produce the semiconductor power module 10 with the diffusion layer 120 formed thereon (step S18 in FIG. 1).

The planar bonding layer 110 is also producible by the production method described above. This accordingly enables the semiconductor device 130 to be bonded to the bonding layer 110 and the bonding layer 110 to be bonded to the ceramic multilayer substrate 100 via the planes and improves the thermal conduction performance from the semiconductor device 130 to the ceramic multilayer substrate 100 and the bond strength between the ceramic multilayer substrate 100 and the semiconductor device 130.

### G2. Modification 2

The method of producing the semiconductor power module 10 may temporary stack a manufactured insulating bonding part 112 without through holes for formation of the conductive connectors 111a on the ceramic multilayer substrate 100 and subsequently create through holes for formation of the conductive bonding parts 111a in the bonding layer, in the insulating bonding part 112 temporary adhered with the multilayer substrate 100 by laser processing. This prevents the through holes from being crushed in the course of tentative compression and enables more accurate control of the aperture size in the insulating bonding part 111a. The through holes in a tapered shape may be formed by oblique laser radiation.

### G3. Modification 3

The procedure of the first embodiment temporary stacks the ceramic multilayer substrate 100 and the bonding layer 110 by the binding force of the organic binder and subsequently stacks the semiconductor device 130 to be bonded by application of pressure and heat. A modified procedure may, for example, manufacture a sheet of insulating bonding part 112 having holes pre-filled with conductive connectors 111a, place the sheet between the ceramic multilayer substrate 100 and the semiconductor device 130 and apply heat and pressure to produce the semiconductor power module 10. This enables reduction in amount of the organic binder included in the bonding layer 110 and thereby prevents degradation of the bonding layer 110 by the organic residue.

### G4. Modification 4

According to the first embodiment, the temperature that sufficiently melts the material constituting the conductive bonding parts 111 is used as the first bonding start temperature, and the temperature that sufficiently softens the material constituting the insulating bonding parts 112 is used as the second bonding start temperature. Each of these bonding start temperatures may, however, be any temperature that is not lower than the temperature at which at least part of the constituent material starts a sintering reaction. This enables the conductive bonding parts 111 or the insulating bonding parts 112 to be bonded to another member without being heated to the melting point. This enables the lower-temperature manufacturing process. For example, when the insulating bonding parts 112 are made of powder glass including Na₂O₃, B₂O₃ and SiO₂, the second bonding start temperature may be any temperature that is not lower than 495° C. which is the start temperature of the sintering reaction of the powder glass.

### G5. Modification 5

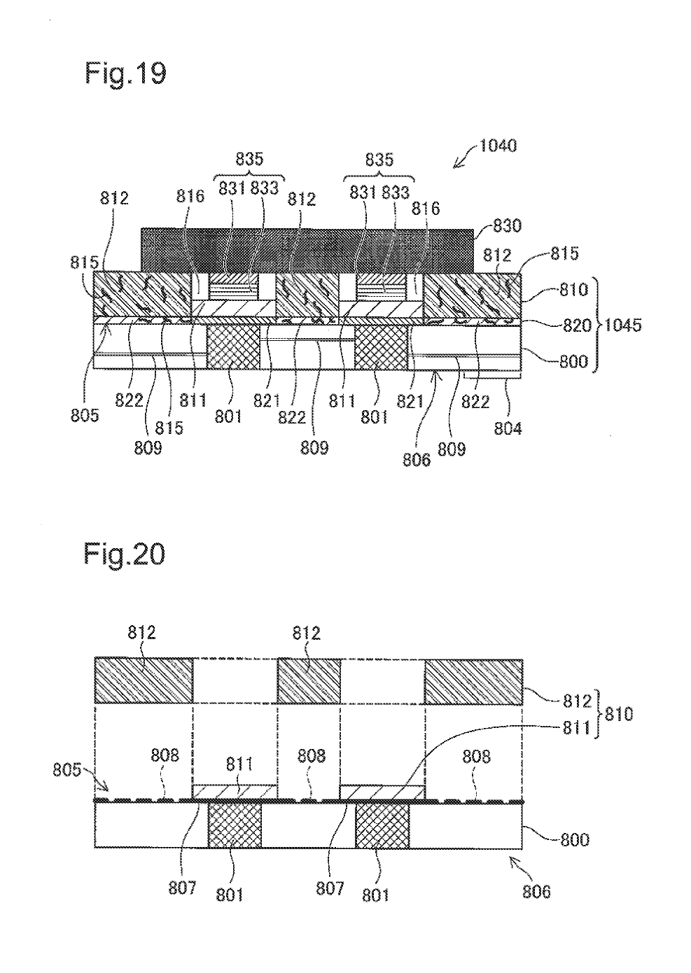

FIG. 19 is a diagram illustrating the schematic configuration of a semiconductor power 1040 according to Modification 5. The semiconductor power 1040 includes a circuit board 1045 and a semiconductor device 830. The circuit board 1045 includes a ceramic multilayer substrate 800, a bonding layer 810 and a diffusion layer 820. The bonding layer 810 includes conductive connectors 811 and insulating bonding parts 812. The ceramic multilayer substrate 800, the bonding layer 810, the conductive connectors 811 and the semiconductor device 830 of Modification 4 have the same configurations as those of the ceramic multilayer substrate 500, the bonding layer 510, the conductive connectors 511 and the semiconductor device 530 of the fifth embodiment.

It is preferable that the insulating bonding parts 812 contain a filler 815 made of a metal material or an inorganic material to such an extent that does not deteriorate the insulation performance. Inclusion of the metal filler or the inorganic filler 815 improves the heat transfer performance of the insulating bonding parts 812. The insulating bonding parts 812 have the similar configuration to that of the insulating bonding part 512 of the fifth embodiment, except that the filler 815 is contained.

The diffusion layer 820 is a layer formed by diffusion bonding between the ceramic multilayer substrate 800 and the bonding layer 810. The diffusion layer 820 includes conductive diffusive parts 821 and insulating diffusive parts 822. The conductive diffusive parts 821 are formed by diffusion bonding between the ceramic multilayer substrate 800 and the conductive connectors 811 of the bonding layer 810. The insulating diffusive parts 822 are formed by diffusion bonding between the ceramic multilayer substrate 800 and the insulating bonding parts 812 of the bonding layer 810. Like the insulating bonding parts 812, the insulating diffusive parts 822 may contain the filler 815. For the purpose of illustration, the boundaries between the conductive diffusive parts 821 and the insulating diffusive parts 822 are clearly shown in FIG. 19. The boundaries between the conductive diffusive parts 821 and the insulating diffusive parts 822 may, however, be unclear.

FIG. 20 is a diagram illustrating the process of arranging the bonding layer 810 in Modification 5. This arranging process is subsequent to step S100 of the fifth embodiment shown in FIG. 12.

The procedure arranges the conductive connectors 811 on a first surface 805 of the ceramic multilayer substrate 800 or specifically at regions 807 corresponding to inner layer via holes 801. More specifically, the procedure prints a paste made of, as the main constituent a metal species which is melted by the heating process at step S110 in FIG. 12, at the regions 807 on the first surface 805 of the ceramic multilayer substrate 800 by screen printing. Transfer printing using a photolithographic pattern may replace screen printing.

The procedure subsequently arranges the insulating bonding parts 812 on the first surface 805 of the ceramic multilayer substrate 800 or specifically at regions 808 different from the regions 807.

More specifically, the procedure kneads powder glass and a pyrolytic organic binder with a solvent such as an organic solvent or water to produce a glass powder paste and prints the glass powder paste at the regions 808 on the first surface 805 of the ceramic multilayer substrate 800 by screen printing to fill the gaps between the conductive connectors 811. The glass powder paste constituting the insulating bonding parts 812 is printed to have the greater thickness than the thickness of the conductive connectors 811.

Arranging the conductive connectors 811 and the insulating bonding parts 812 as described above forms recesses 816 (FIG. 19).

In the semiconductor power 1040 of Modification 5, the diffusion layer 820 is formed between the ceramic multilayer substrate 800 and the bonding layer 810 during diffusion bonding between the ceramic multilayer substrate 800 and the bonding layer 810. This improves the bond strength between the ceramic multilayer substrate 800 and the bonding layer 810.

In the semiconductor power 1040 of Modification 5, inclusion of the filler 815 in the insulating bonding parts 812 of the bonding layer 810 and in the insulating diffusive parts 822 of the diffusion layer 820 improves the heat diffusion performance from the semiconductor device 830 to the ceramic multilayer substrate 800.

### G6. Modification 6

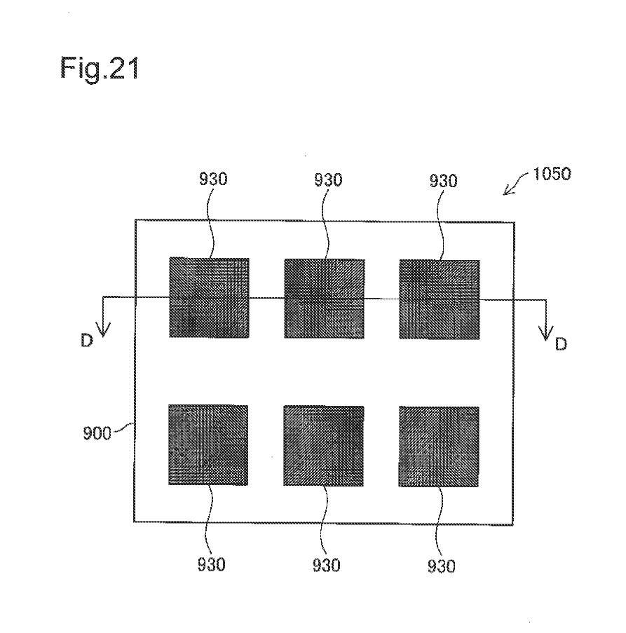

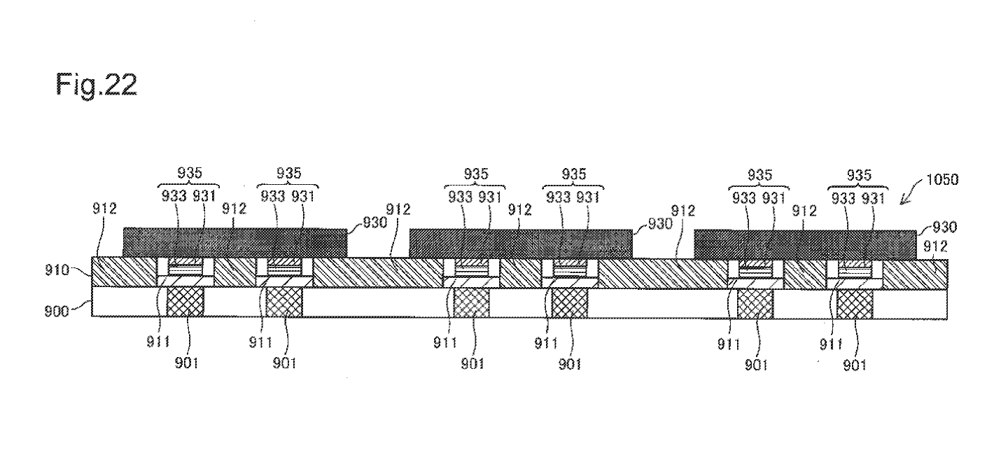

FIG. 21 is a plan view illustrating a semiconductor power module 1050 according to Modification 6. FIG. 22 is a cross sectional view illustrating the semiconductor power module 1050 of Modification 6. FIG. 22 shows a cross section, taken on the line D-D in FIG. 21.

As shown in FIGS. 21 and 22, the semiconductor power module 1050 of Modification 6 includes a ceramic multilayer substrate 900, a bonding layer 910 and a plurality of (six in Modification 6) semiconductor devices 930. The bonding layer 910 includes conductive connectors 911 and an insulating bonding part 912. The semiconductor device 930 includes projections 935, each including an electrode pad 531 and a bump 533. The ceramic multilayer substrate 900, the bonding layer 910, the conductive connectors 911, the insulating bonding part 912 and each of the semiconductor devices 930 of Modification 6 respectively have the same configurations as those of the ceramic multilayer substrate 500, the bonding layer 510, the conductive connectors 511, the insulating bonding part 512 and the semiconductor device 530 of the fifth embodiment.

In general, in response to an increase in allowable amount of heat generation of the semiconductor device accompanied with a change from the conventional Si semiconductor device to the compound semiconductor device such as SiC, the semiconductor device is required to have high heat resistance to the peripheral members. In response to a demand for downsizing of a radiator component as a module, on the other hand, the semiconductor device is required to have high heat diffusivity. In the semiconductor power module 1050 of Modification 6, the bonding layer 910 is made planar, so that the semiconductor devices 930 and the ceramic multilayer substrate 900 are bonded to each other not via an organic material having low heat resistance and heat diffusion properties but via a plane made of, as the main constituent, an inorganic material having excellent heat resistance and heat diffusion properties. This accordingly improves the heat diffusion performance from the semiconductor devices 930 to the ceramic multilayer substrate 900 and thereby provides the semiconductor power module 1050 of the high reliability with a plurality of compound semiconductor devices (semiconductor devices 930), which are usable in a high temperature range of or above about 300° C., mounted at the high density.

### G7. Modification 7

The semiconductor power module 1010 may be produced by the following method, in place of the production method of the semiconductor power module 1010 (FIG. 12) according to the fifth embodiment. The following describes a modified procedure, subsequent to step S100. The respective members are expressed by the same numerals and symbols as those of the fifth embodiment.

The procedure forms an insulating bonding part 512. More specifically the procedure kneads powder glass and a pyrolytic organic binder (for example, butyral binder that is softened at the temperature of about 80° C. and is thermally decomposed at the temperature of about 250° C.) with a solvent such as an organic solvent or water to produce a slurry and molds the slurry in a sheet form by a technique, such as sheet casting according to the doctor blade method or extrusion molding. The procedure subsequently creates opening portions 515 at regions corresponding to the conductive connectors 511 in the sheet by machining process, such as laser processing or microcomputer punching. In this manner, the insulating bonding part 512 is manufactured as the glass sheet with the opening portions 515.

The procedure places the ceramic multilayer substrate 500, such that the first surface 105 of the ceramic multilayer substrate 500 is opposed to a desired surface of the insulating bonding part 512, and applies heat and pressure to the ceramic multilayer substrate 500 and the insulating bonding part 512 to a temperature equal to or higher than the softening temperature of the organic binder included in the sheet of insulating bonding part, so as to temporary adhere the ceramic multilayer substrate 500 with the insulating bonding part 512 by the binding force of the organic binder included in the sheet of insulating bonding part 512.

The procedure subsequently forms conductive connectors 511. More specifically, the procedure partially fills a paste for forming the conductive connectors 511 into the through holes of the manufactured insulating bonding part 512 by screen printing. The paste is made of a metal as the main constituent and may be produced, for example, by kneading a metal species which is melted by the heating process at step S112 in FIG. 12, such as metal aluminum, silver oxide, copper, nanometal or solder alloy and a pyrolytic organic binder with a solvent such as an organic solvent or water. The technique employed for filling the paste is not limited to screen printing but may be, for example, discharge with a dispenser. Placement of the conductive connectors 511 in the opening portions 515 forms the recesses 516.

The procedure then places the semiconductor device 530 on the surface of the bonding layer 110 having the recesses 516 formed thereon by aligning the projections 535 with the recesses 516. The procedure heats the semiconductor device 530 to a temperature that is equal to or higher than the melting points of the glass and the metal as the main constituents of the insulating bonding part 512 and the conductive connectors 511, applies pressure to bond the semiconductor device 530 to the ceramic multilayer substrate 500 and the conductive connectors 511 and the insulating bonding part 512 stacked as described above, and removes the organic binder component included in the insulating bonding part 512 by thermal decomposition, so as to produce the semiconductor power module 1010 (step S112 in FIG. 12).

The planar bonding layer 510 is also producible by the production method described above. This accordingly enables the semiconductor device 530 to be bonded to the bonding layer 510 and the bonding layer 510 to be bonded to the ceramic multilayer substrate 500 via the planes and improves the thermal conduction performance from the semiconductor device 530 to the ceramic multilayer substrate 500 and the bond strength between the ceramic multilayer substrate 500 and the semiconductor device 530.

### G8. Modification 8

The procedure of the fifth embodiment temporary stacks the ceramic multilayer substrate 500 and the conductive connectors 511 and the insulating bonding part 512 by the binding force of the organic binder and subsequently stacks the semiconductor device 530 to be bonded by application of pressure and heat. A modified procedure may, for example, manufacture a sheet of insulating bonding part 512 having holes pre-filled with conductive connectors 511, place the sheet between the ceramic multilayer substrate 500 and the semiconductor device 530 and apply heat and pressure to produce the semiconductor power module 1010. This enables reduction in amount of the organic binder included in the bonding layer 510 and thereby prevents degradation of the bonding layer 510 by the organic residue.

### G9. Modification 9

The procedure of Modification 7 places the glass sheet having the opening portions 515 formed in advance by machining process such as laser processing or microcomputer punching, on the ceramic multilayer substrate 500 and bonds the glass sheet to the ceramic multilayer substrate 500 by thermal compression. Like Modification 2, however, a modified procedure may bond a glass sheet without apertures with the ceramic multilayer substrate 500 by thermal compression and subsequently form the opening portions 515 by, for example, laser processing. This suppresses deformation of the opening portions 515 in the course of thermal compression and enables accurate control of the aperture size of the opening portions 515.

### G10. Modification 10

The projections 535 may have the greater height than the depth of the recesses 516 in the stacking direction. This ensures the good electrical connection between the projections 535 and the conductive connectors 511 when the semiconductor device 530 is set in the recesses 516. In the case where the projections 535 are formed to have the greater height than the depth of the recesses 516 in the stacking direction, the semiconductor device 530 is off the surface of the bonding layer 510 when the semiconductor device 530 is placed on the bonding layer 510. The bonding process, however, applies heat to melt the bumps 533 and applies pressure in this molten state, so that the semiconductor device 530 is bonded to the bonding layer 510 via a void-free plane.

The invention is not limited to the above embodiments, examples or modifications, but a diversity of variations and modifications may be made to the embodiments without departing from the scope of the invention. For example, the technical features of the embodiments, examples or modifications corresponding to the technical features of the respective aspects described in SUMMARY OF INVENTION may be replaced or combined appropriately, in order to solve part or all of the problems described above or in order to achieve part or all of the advantageous effects described above. Any of the technical features may be omitted appropriately unless the technical feature is described as essential herein.

### REFERENCE SIGNS LIST

10, 30, 40 . . . semiconductor power module
100 . . . ceramic multilayer substrate
101 . . . inner layer via hole
104 . . . electrode terminal
109 . . . interconnecting pattern
110 . . . bonding layer
110a . . . bonding part
111 . . . conductive bonding part
111a . . . conductive connector
112 . . . insulating bonding part
120 . . . diffusion layer
121 . . . conductive diffusive part
122 . . . insulating diffusive part
130 . . . semiconductor device
131 . . . electrode pad
202 . . . screen
203 . . . squeegee
204 . . . squeegee holder
250 . . . glass powder paste
300 . . . ceramic multilayer substrate
310 . . . bonding layer
320 . . . diffusion layer
330 . . . semiconductor device
400 . . . ceramic multilayer substrate
410 . . . bonding layer
411 . . . conductive bonding part
412 . . . insulating bonding part
420 . . . diffusion layer
430 . . . semiconductor device
500 . . . ceramic multilayer substrate
501 . . . inner layer via hole
504 . . . electrode terminal
505 . . . first surface
506 . . . second surface
509 . . . interconnecting pattern
510 . . . bonding layer
511 . . . conductive connector
512 . . . insulating bonding part
515 . . . opening portion
515a . . . inner circumferential surfaces
516 . . . recess
518 . . . glass powder paste
530 . . . semiconductor device
531 . . . electrode pad
533 . . . bump
535 . . . projection
600 . . . screen printing machine
602 . . . screen
603 . . . squeegee
604 . . . squeegee holder
650 . . . paste
700 . . . ceramic multilayer substrate
701 . . . inner layer via hole
710 . . . bonding layer
711 . . . conductive connector
712 . . . insulating bonding part
715 . . . opening portion
716 . . . recess
730 . . . semiconductor device
731 . . . electrode pad
733 . . . bump
735 . . . projection
800 . . . ceramic multilayer substrate
801 . . . inner layer via hole
805 . . . first surface
810 . . . bonding layer
811 . . . conductive connector
812 . . . insulating bonding part
815 . . . filler
815 . . . inorganic filler
816 . . . recess
820 . . . diffusion layer
821 . . . conductive diffusive part
822 . . . insulating diffusive part
830 . . . semiconductor device
900 . . . ceramic multilayer substrate
910 . . . bonding layer
911 . . . conductive connector
912 . . . insulating bonding part
930 . . . semiconductor device
935 . . . projection
1010 . . . semiconductor power module
1020 . . . circuit board
1030 . . . semiconductor power module
1040 . . . semiconductor power
1045 . . . circuit board
1050 . . . semiconductor power module

1. A semiconductor power module comprising:
a multilayer substrate having a via and an interconnecting pattern formed thereon;
a semiconductor device placed on a first surface side of the multilayer substrate; and
a bonding layer formed on the first surface of the multilayer substrate for bonding the multilayer substrate to the semiconductor device, wherein
the bonding layer includes:
a planar conductive bonding part arranged at a first region corresponding to the via and configured to have a conductive projection formed on the semiconductor device and a conductive connector arranged to provide electrical continuity between the projection and the multilayer substrate; and
a planar insulating bonding part arranged at a second region different from the first region and made of an inorganic material as a main constituent.

2. The semiconductor power module according to claim 1, wherein
the multilayer substrate and the bonding layer are bonded by diffusion bonding, and the semiconductor device and the bonding layer are bonded by diffusion bonding, and
the semiconductor power module further comprises:
a diffusion layer formed between the multilayer substrate and the bonding layer and between the semiconductor device and the bonding layer during the diffusion bonding.

3. The semiconductor power module according to claim 1, wherein
a first bonding start temperature which is a bonding start temperature of a material constituting the conductive bonding part is lower than a second bonding start temperature which is a bonding start temperature of a material constituting the insulating bonding part.

4. The semiconductor power module according to claim 3, wherein
the first bonding start temperature is equal to or higher than a sintering start temperature at which at least part of the material constituting the conductive bonding part starts a sintering reaction, and
the second bonding start temperature is equal to or higher than a sintering start temperature at which at least part of the material constituting the insulating bonding part starts a sintering reaction.

5. A production method of a semiconductor power module comprising:
a substrate manufacturing step that manufactures a multilayer substrate having a via and an interconnecting pattern;
a first placement step that places a bonding part on a first surface of the multilayer substrate, wherein the bonding part has a planar conductive connector for providing electrical continuity between the interconnecting pattern and a semiconductor device at a first region corresponding to the via and a planar insulating bonding part at a second region different from the first region;
a second placement step that places the semiconductor device on the bonding part such as to provide electrical continuity between a conductive projection formed on the semiconductor device and the conductive connector; and
a bonding step that bonds the multilayer substrate, the bonding part and the semiconductor device by application of heat and pressure, so as to make diffusion bonding between the multilayer substrate and the bonding part and between the bonding part and the semiconductor device.

6. The production method of the semiconductor power module according to claim 5, wherein
a first bonding start temperature is a temperature at which a material constituting the conductive connector starts bonding to the semiconductor device, and
a second bonding start temperature is a temperature at which a material constituting the insulating bonding part starts bonding to the multilayer substrate and to the semiconductor device and which is higher than the first bonding start temperature, wherein
the bonding step includes:
a step of bonding the multilayer substrate, the bonding part and the semiconductor device by application of pressure and heat at the first bonding start temperature, so as to bond the conductive connector to the projection of the semiconductor device; and
a step of bonding the multilayer substrate, the bonding part and the semiconductor device by application of pressure and heat at the second bonding start temperature, so as to bond the multilayer substrate to the bonding part and bond the bonding part to the semiconductor device, after the conductive connector is bonded to the projection of the semiconductor device.

7. The production method of the semiconductor power module according to claim 6, wherein
the first bonding start temperature is equal to or higher than a sintering start temperature at which at least part of the material constituting the conductive connector starts a sintering reaction, and
the second bonding start temperature is equal to or higher than a sintering start temperature at which at least part of the material constituting the insulating bonding part starts a sintering reaction.

8. The production method of the semiconductor power module according to claim 5, wherein
a first bonding start temperature is a temperature at which a material constituting the conductive connector starts bonding to the semiconductor device, and
a second bonding start temperature is a temperature at which a material constituting the insulating bonding part starts bonding to the multilayer substrate and to the semiconductor device and which is higher than the first bonding start temperature, wherein
the bonding step performs the application of heat, based on a temperature profile which is set to maintain the first bonding start temperature for a predetermined time and subsequently maintain the second bonding start temperature for a predetermined time.

9. The production method of the semiconductor power module according to claim 5, wherein
the first placement step includes:
a step of placing the insulating bonding part having an opening portion at the first region on the first surface; and
a step of placing the conductive connector made thinner than the insulating bonding part in the opening portion, and
the second placement step includes:
a step of placing the semiconductor device on the bonding part such that the projection is fit in the opening portion, so as to provide electrical continuity between the projection of the semiconductor device and the conductive connector, and wherein
d3>d2−d1 is satisfied where d1 represents a thickness of the conductive connector, d2 represents a thickness of the insulating bonding part and d3 represents a height of the projection.

10. The production method of the semiconductor power module according to claim 9, wherein
the step of placing the insulating bonding part arranges the insulating bonding part to be in such a shape that narrows from an end bonded to the semiconductor device toward an end bonded to the multilayer substrate.

11. The production method of the semiconductor power module according to claim 10, wherein
the step of placing the insulating bonding part arranges the insulating bonding part to be in a tapered shape.

12. A circuit board substrate comprising:
a multilayer substrate having a via and an interconnecting pattern formed thereon; and
a bonding layer formed on a first surface of the multilayer substrate for bonding the multilayer substrate to a semiconductor device, wherein
the bonding layer includes:
a conductive connector arranged at a first region corresponding to the via and configured to provide electrical continuity with the interconnecting pattern and with the semiconductor device, wherein at least a first surface-side surface of the conductive connector is made planar; and
an insulating bonding part arranged at a second region different from the first region and made of an inorganic material as a main constituent, wherein at least a first surface-side surface of the insulating bonding part is made planar.

13. The circuit substrate according to claim 12, wherein
the conductive connector is made thinner than the insulating bonding part, and
the bonding layer has a recess formed by the insulating bonding part and the conductive connector, and wherein
before a conductive projection formed on the semiconductor device is fit in the recess, d3>d2−d1 is satisfied where d1 represents a thickness of the conductive connector, d2 represents a thickness of the insulating bonding part and d3 represents a height of the projection.

14. The circuit substrate according to claim 12, wherein
the insulating bonding part is formed in such a shape that narrows from an end bonded to the semiconductor device toward an end bonded to the multilayer substrate.

15. The circuit substrate according to claim 12, wherein
the insulating bonding part is formed in a tapered shape.
